(19) United States
(12) Patent Application Publication
(10) Pub. No.: US 2026/0096374 A1
(43) Pub. Date: Apr. 2, 2026

(54) SUBSTRATE PROCESSING APPARATUS

(71) Applicant: SCREEN Holdings Co., Ltd., Kyoto (JP)

(72) Inventor: Hiromichi KABA, Kyoto (JP)

(21) Appl. No.: 19/112,592

(22) PCT Filed: Aug. 14, 2023
(86) PCT No.: PCT/JP2023/029415

§ 371 Date: Mar. 17, 2025

(30) Foreign Application Priority Data
Sep. 22, 2022 (JP) 2022-151711

(51) Int. Cl. H10P 72/00; H10P 72/30

(52) U.S. Cl. CPC H10P 72/0408; H10P 72/0426; H10P 72/3211; H10P 72/3306; H10P 72/3311

(57) ABSTRACT

There is provided a substrate processing apparatus in which throughput is improved by increasing the number of disposed single wafer type chambers while suppressing the size of the apparatus. According to the present invention, the single wafer type chambers can be stacked in a vertical direction, it is possible to provide a substrate processing apparatus in which more single wafer type chambers are mounted even in the same floor area as that of a conventional apparatus. Further, when a mechanism for carrying a substrate W into a single wafer type chamber (drying chamber) and a mechanism for carrying the substrate W out of the drying chamber are provided independently, the substrate can be smoothly transferred around the drying chamber. According to the present invention, it is possible to provide a substrate processing apparatus 1 having a small size and a high throughput.

### TECHNICAL FIELD

The present invention relates to a substrate processing apparatus that performs predetermined processing on various substrates such as a semiconductor substrate, a substrate for a flat panel display (FPD) such as a liquid crystal display or an organic electroluminescence (EL) display device, a glass substrate for a photomask, and a substrate for an optical disk.

### BACKGROUND ART

Conventionally, this type of apparatus includes a batch type module and a single wafer type module (see, for example, Patent Literature 1). The batch type module collectively performs predetermined processing on a plurality of substrates. The single wafer type module performs predetermined processing on each substrate. Each of the batch type module and the single wafer type module has unique advantages. For example, the single wafer type module has higher particle performance in a drying treatment than the batch type module. Therefore, as an apparatus including a batch type module or a single wafer type module, a configuration is conceivable in which liquid treatment is performed in the batch type module, and then drying treatment is performed in the single wafer type module.

In the apparatus described in Patent Literature 1, single wafer type chambers that perform drying treatment are arranged in a row in a horizontal direction. A substrate after batch processing is subjected to a drying treatment in any of a plurality of single wafer type chambers. That is, the substrate after the batch processing is transferred by a transfer mechanism movable in an arrangement direction of the single wafer type chambers, and is introduced into a single wafer type chamber capable of receiving the substrate. When the batch processing is completed, the plurality of substrates is in a standby state for the drying treatment. The single wafer type chamber can perform the drying treatment on the substrate only one by one. Accordingly, in the apparatus described in Patent Literature 1, a plurality of single wafer type chambers is mounted on the apparatus for the purpose of increasing throughput, and the drying treatment is simultaneously performed on different substrates. In the apparatus described in Patent Literature 1, in order to quickly complete the drying treatment on the plurality of substrates, it is only necessary to arrange as many single wafer type chambers as possible in a row in the horizontal direction.

### CITATION LIST

### Patent Literature

Patent Literature 1: JP 2016-502275 A

### SUMMARY OF INVENTION

### Technical Problem

However, the conventional apparatus having such a configuration has the following problems.

That is, in the conventional apparatus, if the single wafer type chambers are added, the size of the apparatus increases accordingly. According to the conventional configuration, when the single wafer type chambers are to be added, since the single wafer type chambers are only arranged in a row in the horizontal direction, the length of the substrate processing apparatus is extended by the number of single wafer type chambers. There is a limit to an allowable length in the substrate processing apparatus. In order to follow the limit, according to the conventional configuration, the number of single wafer type chambers has to be limited. According to such an apparatus, the processing speed of the single wafer type chambers becomes a bottleneck in the processing speed of the entire apparatus, and the throughput as the entire processing is low.

The present invention has been made in view of such circumstances, and an object thereof is to provide a substrate processing apparatus in which throughput is improved by increasing the number of disposed single wafer type chambers while suppressing the size of the apparatus.

### Solution to Problem

In order to achieve such an object, the present invention has the following configuration.

A substrate processing apparatus that continuously performs batch processing of collectively processing a plurality of substrates and single wafer processing of processing substrates one by one, the substrate processing apparatus including a supply block that supplies a plurality of substrates, a transfer block adjacent to the supply block, and a processing block adjacent to the transfer block, in which the supply block includes a collective transfer mechanism that carries out the plurality of substrates in a horizontal attitude and arranged at predetermined intervals in a vertical direction from a carrier and sends the substrates to a forward substrate handover position in the transfer block, and receives a plurality of substrates in the horizontal attitude and arranged at the predetermined intervals in the vertical direction from a return substrate handover position in the transfer block and stores the substrates in the carrier, the transfer block includes a first attitude changing mechanism that collectively holds the plurality of substrates waiting at the forward substrate handover position and collectively changes an attitude of the plurality of substrates from the horizontal attitude to a vertical attitude, and a vertical substrate support member that causes the plurality of substrates in the vertical attitude to wait at a vertical substrate handover position in the transfer block, the processing block includes a batch processing region having one end side adjacent to the transfer block and another end side extending in a direction away from the transfer block, a single wafer processing region having one end side adjacent to the transfer block and another end side extending in the direction away from the transfer block, a single substrate transfer region interposed between the batch processing region and the single wafer processing region and having one end side adjacent to the transfer block and another end side extending in the direction away from the transfer block, and a batch substrate transfer region provided along the batch processing region and having one end side adjacent to the transfer block and another end side extending in the direction away from the transfer block, in the batch processing region in the processing block, a plurality of batch processing tanks that collectively perform an immersion treatment on the plurality of substrates in a direction in which the region extends is arranged, and a second attitude changing mechanism that collectively changes an attitude of the plurality of substrates from the vertical attitude to the horizontal attitude at a position farthest from the transfer block and a horizontal substrate support member that causes the plurality of substrates in the horizontal attitude to wait at a horizontal substrate handover position in the batch processing region are further provided, in the single wafer processing region in the processing block, a substrate carrying-in mechanism in which a plurality of drying chambers for performing a drying treatment of a substrate is arranged in the vertical direction, and a substrate before the drying treatment is carried into the drying chamber, is further provided, in the single wafer processing region in the processing block, a plurality of drying chambers that performs a drying treatment of substrates in a vertical direction is arranged, and a substrate carrying-in mechanism that carries a substrate before the drying processing into the drying chamber is further provided, in the single substrate transfer region in the processing block, a single substrate transfer mechanism that receives a substrate in the horizontal attitude from the horizontal substrate handover position and transfers the substrate to the single wafer processing region, and a substrate carrying-out mechanism that carries out a substrate after the drying treatment from the drying chamber to the return substrate handover position in the transfer block are provided, and the batch substrate transfer region in the processing block includes the vertical substrate handover position defined in the transfer block, and a batch substrate transfer mechanism that collectively transfers the plurality of substrates between each of the batch processing tanks and the second attitude changing mechanism.

[Operation and Effect] According to the invention according to (1) described above, the substrates are collectively taken out from the carrier that stores the plurality of substrates in the horizontal attitude, and the attitude of the substrates is collectively changed from the horizontal attitude to the vertical attitude by the first attitude changing mechanism. Then, the plurality of substrates is subjected to batch processing in the batch processing region while maintaining the vertical attitude. After the batch processing is performed, the second attitude changing mechanism collectively changes the attitude of the substrates from the vertical attitude to the horizontal attitude. Thereafter, the substrates are subjected to single wafer processing by the single wafer processing region in a state where the horizontal attitude is maintained. The single wafer processing specifically includes substrate drying treatment. The single substrate processing region of the present invention includes a substrate carrying-in mechanism that transfers a wet substrate to be subjected to the drying treatment to the drying chamber, and further includes a substrate carrying-out mechanism that carries out the dried substrate after the drying treatment from the drying chamber. With such a configuration, since the carrying in and carrying out of the substrate into and from the drying chamber can be implemented by different mechanisms, the transfer of the substrate is not congested around the drying chamber. According to the present invention, since the drying chambers are stacked in the vertical direction and the substrate is smoothly transferred around the drying chambers, it is possible to provide a substrate processing apparatus in which many drying chambers are mounted in the same floor area as that of the conventional apparatus.

The present invention also has the following features.
(2) In the substrate processing apparatus according to (1), the substrate carrying-in mechanism receives a substrate from the single substrate transfer mechanism.

[Operation and Effect] According to the invention according to (2) described above, the substrate carrying-in mechanism that carries the substrate into the drying chamber receives the substrate from the single substrate transfer mechanism located in the batch processing region. With this configuration, the substrate carrying-in mechanism can be disposed at a position away from the batch processing region. Therefore, according to the invention according to (2), a plurality of stacks of the drying chambers can be provided around the substrate carrying-in mechanism, and a substrate processing apparatus with a high throughput can be provided.
(3) In the substrate processing apparatus according to (1), the single wafer processing region includes a substrate drying pretreatment chamber that performs a pretreatment of the drying treatment, the single substrate transfer mechanism delivers a substrate to the substrate drying pretreatment chamber, and the substrate carrying-in mechanism receives a substrate from the substrate drying pretreatment chamber.

[Operation and Effect] According to the invention according to (3) described above, the single substrate transfer mechanism sends the substrate to the substrate drying pretreatment chamber, and the substrate carrying-in mechanism receives the substrate from the substrate drying pretreatment chamber. With this configuration, it is not necessary to transfer the substrate between the substrate carrying-in mechanism and the single substrate transfer mechanism, and thus it is possible to provide a substrate processing apparatus capable of more reliably transferring the substrate and reliably pretreating the substrate to be dried.
(4) In the substrate processing apparatus according to (2), the single substrate transfer mechanism is constituted by a robot that also serves as the substrate carrying-out mechanism, the single substrate transfer mechanism includes a handover arm that supports the substrate before the drying treatment, the substrate carrying-out mechanism includes a carrying-out arm that supports the substrate after the drying treatment, and the carrying-out arm is provided in an upper portion of the handover arm.

[Operation and Effect] According to the invention according to (4) described above, the single substrate transfer mechanism includes a robot that also serves as the substrate carrying-out mechanism, and the carrying-out arm that supports the substrate after the drying treatment is provided above the handover arm that supports the substrate before the drying treatment. With this configuration, there is no possibility that the liquid drips from the handover arm that transfers the wet substrate to the carrying-out arm that transfers the dried substrate and adversely affects the substrate.
(5) In the substrate processing apparatus according to (1), the drying chamber dries the substrate with a supercritical fluid.

[Operation and Effect] According to the invention according to (5) described above, since the substrate is dried in a state where the surface tension is 0, pattern collapse of a circuit provided on the substrate surface does not occur.
(6) In the substrate processing apparatus according to (3), the substrate drying pretreatment chamber predries the substrate with isopropyl alcohol.

[Operation and Effect] According to the invention according to (6) described above, pretreatment of substrate drying can be reliably performed with isopropyl alcohol.
(7) In the substrate processing apparatus according to (1), in the single wafer processing region in the processing block, stacks of the drying chambers are provided on both sides of the substrate carrying-in mechanism.

[Operation and Effect] According to the invention according to (7) described above, the stacks of drying chambers are provided on both sides of the substrate carrying-in mechanism in the single wafer processing region. With this configuration, since the number of drying chambers facing the substrate carrying-in mechanism can be increased, the drying treatment can be performed on more substrates in parallel. With this configuration, a substrate processing apparatus having a high throughput can be provided.
(8) In the substrate processing apparatus according to (1), in the batch substrate transfer region in the processing block, a first substrate carrying-out mechanism that carries out a substrate in an upper layer of the stacks of the drying chamber, and a second substrate carrying-out mechanism that carries out a substrate in a lower layer of the stacks of the drying chamber are provided, and in the transfer block, a first return substrate handover position at which the first substrate carrying-out mechanism carries out a substrate is set, and a second return substrate handover position at which the second substrate carrying-out mechanism carries out a substrate is set.

[Operation and Effect] According to the invention according to (8) described above, there is a plurality of paths through which the substrate subjected to the drying treatment returns to the carrier. Then, the first substrate carrying-out mechanism and the second substrate carrying-out mechanism respectively correspond to different paths, the first substrate carrying-out mechanism carries out the substrate transfer in the first path, and the second substrate carrying-out mechanism carries out the substrate transfer in the second path. With this configuration, a substrate processing apparatus having a high throughput can be provided.

### Advantageous Effects of Invention

According to the present invention, it is possible to provide a substrate processing apparatus in which throughput is improved by increasing the number of disposed single wafer type chambers while suppressing the size of the apparatus. In the conventional configuration, when single wafer type chambers are to be added, since the single wafer type chambers are only arranged in a row in the horizontal direction, the length of the substrate processing apparatus is extended by the number of single wafer type chambers. In comparison, according to the present invention, the single wafer type chambers can be stacked in a vertical direction, it is possible to provide a substrate processing apparatus in which more single wafer type chambers are mounted even in the same floor area as that of a conventional apparatus. Further, when a mechanism for carrying a substrate into a single wafer type chamber (substrate drying treatment chamber) and a mechanism for carrying the substrate out of the substrate drying treatment chamber are provided independently, the substrate can be smoothly transferred around the drying chamber. According to the present invention, it is possible to provide a substrate processing apparatus having a small size and a high throughput.

### BRIEF DESCRIPTION OF DRAWINGS

FIG. 1 is a plan view describing an overall configuration of a substrate processing apparatus according to a first embodiment.

FIG. 2 is a functional block diagram illustrating a configuration of a collective transfer mechanism according to the first embodiment.

FIG. 3 is a perspective view illustrating a configuration of a collective gripping hand according to the first embodiment.

FIG. 4 is a functional block diagram illustrating a configuration of a first attitude changing mechanism according to the first embodiment.

FIG. 5 is a functional block diagram illustrating a configuration of a substrate pickup mechanism according to the first embodiment.

FIG. 6 is a schematic view describing transfer of a substrate in a transfer block according to the first embodiment.

FIG. 7 is a schematic view describing transfer of a substrate in the transfer block according to the first embodiment.

FIG. 8 is a schematic view describing transfer of a substrate in the transfer block according to the first embodiment.

FIG. 9 is a schematic view describing transfer of the substrate in the transfer block according to the first embodiment.

FIG. 10 is a schematic view describing transfer of the substrate in the transfer block according to the first embodiment.

FIG. 11 is a schematic view describing operation of the substrate pickup mechanism in the transfer block according to the first embodiment.

FIG. 12 is a perspective view describing the operation of the substrate pickup mechanism in the transfer block according to the first embodiment.

FIG. 13 is a schematic view describing the operation of the substrate pickup mechanism in the transfer block according to the first embodiment.

FIG. 14 is a schematic view describing transfer of the substrate in the transfer block according to the first embodiment.

FIG. 15 is a schematic view describing the operation of the substrate pickup mechanism in the transfer block according to the first embodiment.

FIG. 16 is a schematic view describing operation of a pusher mechanism in the transfer block according to the first embodiment.

FIG. 17 is a perspective view illustrating a configuration of a second attitude changing mechanism according to the first embodiment.

FIG. 18 is a schematic view describing operation of the second attitude changing mechanism according to the first embodiment.

FIG. 19 is a side view illustrating a configuration of a single wafer processing region according to the first embodiment.

FIG. 20 is a plan view describing a configuration of a drying chamber according to the first embodiment.

FIG. 21 is a functional block diagram illustrating a configuration of a wet transfer mechanism according to the first embodiment.

FIG. 22 is a functional block diagram illustrating a configuration of a single substrate transfer region according to the first embodiment.

FIG. 23 is a plan view describing the configuration of a substrate carrying-in mechanism according to the first embodiment.

FIG. 24 is a plan view describing transfer of a substrate according to the first embodiment.

FIG. 25 is a flowchart illustrating an operation of the substrate processing according to the first embodiment.

FIG. 26 is a plan view describing a flow of a substrate according to the first embodiment.

FIG. 27 is a plan view describing a flow of a substrate according to the first embodiment.

FIG. 28 is a plan view describing a flow of a substrate according to the first embodiment.

FIG. 29 is a plan view describing an overall configuration of a substrate processing apparatus according to the second embodiment.

FIG. 30 is a side view illustrating a configuration of a single wafer processing region according to the second embodiment.

FIG. 31 is a side view illustrating a configuration of a single substrate transfer region according to the second embodiment.

FIG. 32 is a flowchart illustrating an operation of substrate processing according to the second embodiment.

FIG. 33 is a plan view describing a flow of a substrate according to the second embodiment.

FIG. 34 is a plan view describing a flow of a substrate according to the second embodiment.

FIG. 35 is a plan view describing a flow of a substrate according to the second embodiment.

### DESCRIPTION OF EMBODIMENTS

Hereinafter, embodiments of the present invention will be described with reference to the drawings. The substrate processing apparatus according to the present invention is an apparatus that performs batch processing of collectively processing a plurality of substrates W, and then performs single wafer processing of processing the substrates W one by one.

### First Embodiment

### 1. Overall Configuration

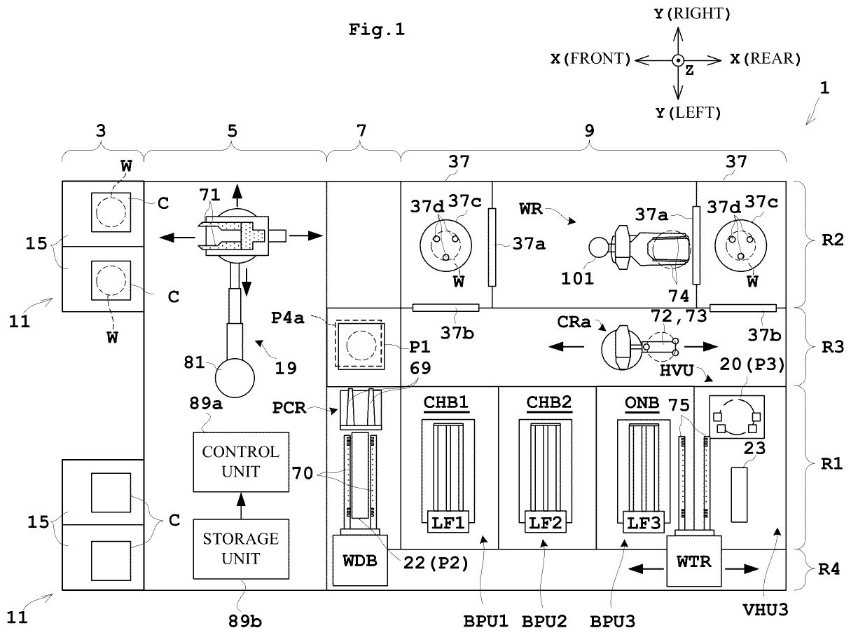

As illustrated in FIG. 1, the substrate processing apparatus 1 includes blocks defined by partition walls. That is, the substrate processing apparatus 1 includes a carry-in/out block 3 on which a carrier for housing a substrate is mounted, a supply block 5 adjacent to the carry-in/out block 3, a transfer block 7 adjacent to the supply block 5, and a processing block 9 adjacent to the transfer block 7. The supply block 5 corresponds to a supply block of the present invention, and the transfer block 7 corresponds to a transfer block 7 of the present invention. The processing block 9 corresponds to a processing block of the present invention.

The substrate processing apparatus 1 performs, for example, predetermined treatments such as a chemical solution treatment, a cleaning treatment, and a drying treatment on the substrate W. The substrate processing apparatus 1 employs a processing method (what is called a hybrid method) in which both a batch type processing method of collectively processing the plurality of substrates W and a single wafer type processing method of processing the substrates W one by one are used in combination. The batch type processing method is a processing method for collectively processing a plurality of substrates W arranged in a vertical attitude. The single wafer processing method is a processing method of processing the substrates W in a horizontal attitude one by one.

In the present specification, for convenience, a direction in which the carry-in/out block 3, the supply block 5, the transfer block 7, and the processing block 9 are arranged is referred to as a “front-rear direction X”. The front-rear direction X extends horizontally. Of the front-rear direction X, the direction from the supply block 5 toward the carry-in/out block 3 is referred to as “front”. A direction opposite to the front is referred to as “rear”. A direction orthogonal to the front-rear direction X is referred to as a “width direction Y”. The width direction Y extends horizontally. One direction in the width direction Y is referred to as a “right side” for convenience, and the opposite direction is referred to as a “left side”. A direction (height direction) orthogonal to the front-rear direction X and the width direction Y is referred to as a “vertical direction Z” for convenience. In each drawing, front, rear, right, left, top, and bottom are appropriately indicated for reference.

### 2. Carry-In/Out Block

The carry-in/out block 3 includes a carrier holding unit 11 that holds a carrier C that arranges and stores the plurality of substrates W in the horizontal attitude at predetermined intervals in the vertical direction. The carrier holding unit 11 is provided on an outer wall of the carry-in/out block 3 extending in the width direction (Y direction). The carrier holding unit 11 includes one provided on the right side as viewed from the central portion in the width direction (Y direction) in the substrate processing apparatus 1 and one provided on the left side. The two carrier holding units 11 are referred to as one load port.

The plurality of (for example, 25) substrates W is stacked and stored in one carrier C at regular intervals in the horizontal attitude. The carrier C storing the substrate W to be processed to be carried into the substrate processing apparatus 1 is first mounted on one of the carrier holding units 11. The carrier holding unit 11 includes, for example, two mounting tables 15 on which the carrier C is mounted. The carrier C is formed with a plurality of grooves (not illustrated) extending in the horizontal direction to accommodate the surfaces of the substrate W in a state of being separated from each other. The plurality of grooves is spaced apart to form a comb shape as a whole. One substrate W is inserted into each of the grooves. Examples of the carrier C include a sealed front opening unify pod (FOUP). In the present invention, an open type container may be employed as the carrier C.

### 3. Supply Block

The supply block 5 has a function of supplying a plurality of substrates to the subsequent transfer block 7. That is, the supply block 5 is provided at a position interposed between the carry-in/out block 3 and the transfer block 7. The supply block 5 includes a collective transfer mechanism 19 that collectively takes out a plurality of substrates from the carrier C held by the carrier holding unit 11 in the carry-in/out block 3 and transfers the substrates to the transfer block 7. A support column 81 extending in the vertical direction Z included in the collective transfer mechanism 19 is provided at a central position in the supply block 5, that is, at a central position in both the X direction and the Y direction, and a collective transfer hand 71 moves up and down, left and right, and front and rear directions with reference to the support column 81. The supply block 5 has a space of a sufficient size so as not to hinder the operation of the collective transfer hand 71.

The collective transfer mechanism 19 has two functions of a function of collectively taking out the plurality of substrates W from the carrier C held by the carrier holding unit 11 in the carry-in/out block 3 and mounting the substrates W at a forward substrate handover position P1 of the transfer block 7, and a function of collectively receiving the plurality of substrates W from a return substrate handover position P4 of the transfer block 7 and returning the substrates W to the carrier C held by the carrier holding unit 11 in the carry-in/out block 3. The collective transfer mechanism 19 transfers the plurality of substrates W from the carrier C to the forward substrate handover position P1 while maintaining the positional relationship among the plurality of substrates W stored in the carrier C. Similarly, the collective transfer mechanism 19 transfers the plurality of substrates W from the return substrate handover position P4 to the carrier C while maintaining the positional relationship of each of the plurality of substrates W arranged at the return substrate handover position P4. By the transfer of the collective transfer mechanism 19, the substrates W to be processed stored in the carrier C are subjected to various processes by the substrate processing apparatus 1, and then returns to the original carrier C. The collective transfer mechanism 19 does not necessarily need to include a mechanism for changing the attitude of the plurality of substrates W. The collective transfer mechanism 19 in the present example transfers the plurality of substrates W from the carrier C to the forward substrate handover position P1 while maintaining the attitude and the arrangement pitch of the substrates W. Therefore, the plurality of substrates W is transferred by the collective transfer mechanism 19 in a state of being arranged at a full pitch in the horizontal attitude. The same applies to the substrate transfer from the return substrate handover position P4 to the carrier C by the collective transfer mechanism 19.

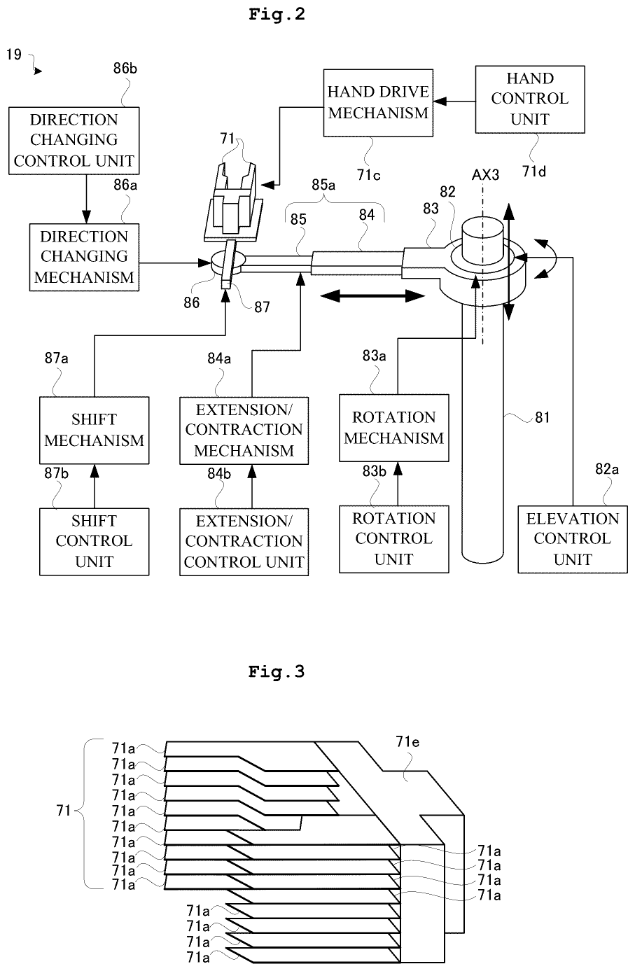

A configuration of the collective transfer mechanism 19 will be described with reference to FIG. 2. FIG. 2 is a functional block diagram illustrating a configuration of the collective transfer mechanism 19. As illustrated in FIG. 2, the collective transfer mechanism 19 includes the support column 81 extending in the vertical direction (Z direction) for supporting each mechanism. The collective transfer mechanism 19 further includes an elevation mechanism 82 that can move up and down. The elevation mechanism 82 is supported by the support column 81 so as to be movable up and down. The elevation mechanism 82 rotatably supports the rotating member 83. The rotating member 83 can rotate about a rotation axis AX3 parallel to an extending direction (Z direction) of the support column 81 in a state of being supported by the elevation mechanism 82. The rotation axis AX3 is a virtual straight line located at the center of the support column 81.

The rotating member 83 supports an extendable arm 85a. The arm 85a includes a first arm 84 connected to the rotating member 83 and a second arm 85 connected to the first arm 84. A connecting portion of the first arm 84 in the rotating member 83 is a protruding portion extending in a direction away from the rotation center of the rotating member 83, and the first arm 84 is configured to extend the protruding portion. The second arm 85 is configured to extend the first arm 84. The rotating member 83 supports the first arm 84 so that the first arm 84 is movable in the extending direction of the first arm 84, and the first arm 84 supports the second arm 85 so that the second arm 85 is movable in the extending direction of the second arm 85. Therefore, the arm 85a is extendable in the extending direction of the first arm 84 and the second arm 85.

A rotatable direction changing member 86 is provided at a distal end of the second arm 85. The direction changing member 86 supports a rail 87 extending in the horizontal direction. Therefore, the collective transfer mechanism 19 is configured to be able to change the extending direction of the rail 87 by rotating the direction change. The direction changing member 86 rotates about an imaginary line which is at the center of the direction changing member 86 and extends in the vertical direction (Z direction). By this rotation, the collective transfer hand 71 can be directed toward the carry-in/out block 3 or toward the transfer block 7.

The rail 87 supports the collective transfer hand 71 that collectively grips the plurality of substrates W so as to be movable in the extending direction of the rail 87. Therefore, the collective transfer hand 71 can advance and retreat along the rail 87. The position of the rail 87 in the vertical direction can be changed by the elevation mechanism 82. The position of the rail 87 on the horizontal plane can be changed by the arm and the rotating member 83. Therefore, the collective transfer hand 71 can freely move in the space in the supply block 5. Then, the direction of the rail 87 can be changed by the direction changing member 86. Therefore, the collective transfer hand 71 can move in the front-rear direction (X direction) at any position in the space in the supply block 5. Therefore, the collective transfer hand 71 can move to the carrier C held by the carrier holding unit 11 in the carry-in/out block 3, and the collective transfer hand 71 can be moved to the inside of the carrier C by moving forward on the rail 87. Then, the collective transfer hand 71 moves back on the rail 87, so that the plurality of gripped substrates W can be taken out from the carrier C. If the reverse of these operations is followed, the collective transfer hand 71 can return the plurality of held substrates W to the carrier C. Although the above-described example relates to the carrier C, the collective transfer hand 71 can take out the plurality of substrates W or perform a transfer operation also at the substrate handover position by a similar operation.

Hereinafter, various mechanisms provided in the collective transfer mechanism 19 and a control unit that controls these mechanisms will be described. An elevation control unit 82a is configured to control the elevation mechanism 82. A rotation mechanism 83a is a mechanism that rotates the rotating member 83 with respect to the elevation mechanism 82, and a rotation control unit 83b is configured to control the rotation mechanism 83a. An extension/contraction mechanism 84a is a mechanism that extends and contracts the arm 85a in the extending direction, and an extension/contraction control unit 84b is configured to control the extension/contraction mechanism 84a. A direction changing mechanism 86a is a mechanism that rotates the direction changing member 86 with respect to the second arm 85, and a direction changing control unit 86b is configured to control the direction changing mechanism 86a. A shift mechanism 87a is a mechanism for advancing and retracting the collective transfer hand 71 with respect to the rail 87, and a shift control unit 87b is configured to control the shift mechanism 87a. A hand drive mechanism 71c is a mechanism that drives the collective transfer hand 71 to cause the collective transfer hand 71 to grip the plurality of substrates W or separate the plurality of substrates W held. A hand control unit 71d is configured to control the hand drive mechanism 71c.

FIG. 3 illustrates a configuration of the collective transfer hand 71. The collective transfer hand 71 is configured by arranging pairs of hand pieces 71a in the vertical direction (Z direction). Each of the pairs of hand pieces 71a is collectively connected to a hand base portion 71e. The hand base portion 71e is configured to be able to advance and retreat on the rail 87. The pairs of hand pieces 71a are provided as many as the number of substrates W stored in the carrier C in the collective transfer hand 71. Accordingly, only 25 pairs of hand pieces 71a are provided in the collective transfer hand 71. In this respect, the hand pieces 71a are reduced in FIG. 3 for convenience of drawing.

### 4. Transfer Block

The transfer block 7 is arranged adjacent to the rear of the supply block 5. The forward substrate handover position Pl at which the substrate W to be processed is mounted is set in the transfer block 7, and the plurality of substrates W is collectively carried into the position from the supply block 5. The transfer block 7 includes a first attitude changing mechanism PCR that can access the forward substrate handover position P1, a substrate pickup mechanism WDB that receives the substrates W in the vertical attitude from the first attitude changing mechanism PCR and makes the arrangement of the substrates W half pitch, and a pusher mechanism 22 that receives the plurality of substrates W from the substrate pickup mechanism WDB and transfers the plurality of substrates W to a vertical substrate handover position P2.

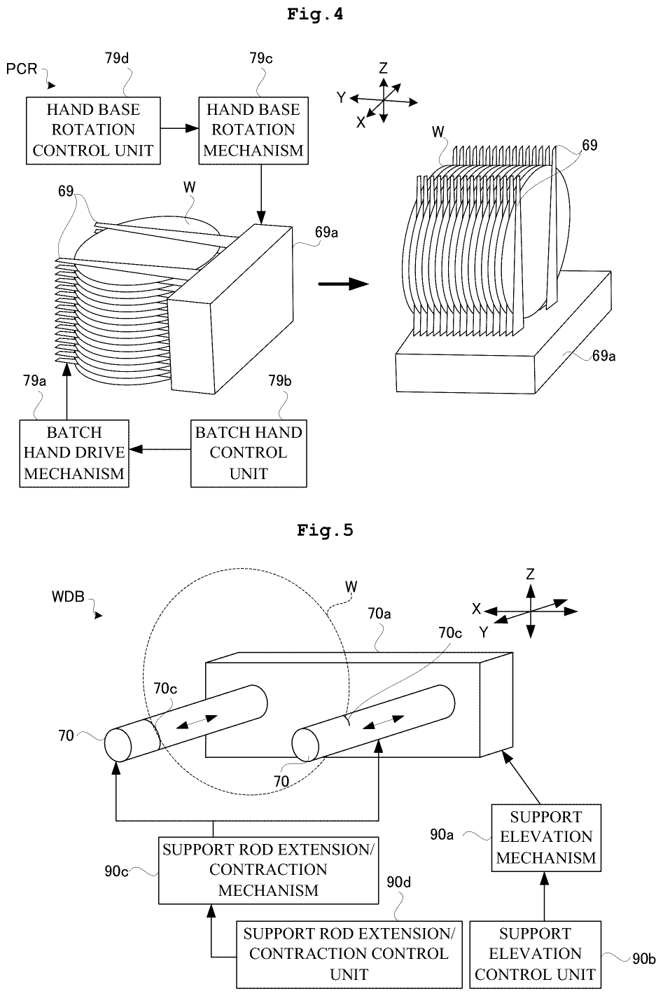

FIG. 4 illustrates a configuration of the first attitude changing mechanism PCR in the present example. As illustrated in FIG. 4, the first attitude changing mechanism PCR includes a batch hand including a pair of clamping hands 69 that clamp the substrate W. Since the clamping hand 69 is configured to clamp the substrate W from both sides of one end and the other end of the substrate W so as to clamp the substrate W, the plurality of substrates W do not slide off the batch hand even when the batch hand is rotated. The batch hand is configured by arranging a pair of clamping hands 69 in the vertical direction (Z direction). Each of the pair of clamping hands 69 is collectively connected to the hand base 69a. The hand base 69a can be rotated by −90° and 90° so that the attitude of the plurality of substrates W in the horizontal attitude is set to the vertical attitude. The pair of clamping hands 69 is provided as many as the number of substrates W stored in the carrier C in the batch hand. Therefore, only 25 pairs of clamping hands 69 are provided in the batch hand. In this regard, the clamping hands 69 are reduced in FIG. 4 for convenience of drawing.

In addition, the first attitude changing mechanism PCR can also move in the width direction (Y direction). That is, the first attitude changing mechanism PCR can access the forward substrate handover position P1 in an attitude capable of holding the substrate W in the horizontal attitude (attitude on the left side in FIG. 4), and can access the substrate pickup mechanism WDB in an attitude capable of holding the substrate W in the vertical attitude (attitude on the right side in FIG. 4).

Hereinafter, various mechanisms provided in the first attitude changing mechanism PCR and a control unit that controls these mechanisms will be described. A batch hand drive mechanism 79a is a mechanism that collectively operates each of the clamping hands 69, and changes the state of the clamping hands 69 between a clamping state in which the plurality of substrates W is clamped and a release state in which the clamping of the plurality of substrates W is released. A batch hand control unit 79b is configured to control the batch hand drive mechanism 79a. The hand base rotation mechanism 79c is a mechanism that rotationally drives the hand base 69a. The attitude of the plurality of substrates is changed from the horizontal attitude to a vertical attitude by the mechanism. The hand base rotation control unit 79d is configured to control the hand base rotation mechanism 79c.

FIG. 5 illustrates the substrate pickup mechanism WDB in the present example. As illustrated in FIG. 5, the substrate pickup mechanism WDB includes two support rods 70 extending in the width direction (Y direction). Each of the support rods 70 is provided with 50 grooves 70c, and a peripheral edge of the substrate W is fitted into these grooves 70c. The arrangement pitch of the grooves 70c is a half pitch. The half pitch is a pitch that is half the arrangement pitch (full pitch) of the substrates W in the plurality of substrates W stored in the carrier C. In FIG. 5, one groove 70c of each of the two support rods 70 is emphasized. The groove 70c of the support rod 70 has a correspondence relationship with the groove 70c of the paired support rod 70, and a pair of grooves 70c is configured to clamp the single substrate W. The front surface and the back surface of the substrate W to be clamped are orthogonal to the width direction (Y direction). Therefore, a distance from the groove 70c into which one end of the substrate W is fitted to a support 70a that supports the support rod 70 is equal to a distance from the groove 70c into which the other end of the substrate W is fitted to the support 70a. Further, the pair of support rods 70 can extend and contract by a distance corresponding to the half pitch without changing the direction in which the clamped substrate W faces. Furthermore, the support 70a itself can move up and down. The substrate W clamped between the pair of support rods 70 and 70 moves up and down along with the vertical movement of the support 70a.

Hereinafter, various mechanisms provided in the substrate pickup mechanism WDB and a control unit that controls these mechanisms will be described. A support elevation mechanism 90a is a mechanism that moves the support 70a in the Z direction to raise and lower the support. A support elevation control unit 90b is configured to control the support elevation mechanism 90a. A support rod extension/contraction mechanism 90c is configured to extend/contract the support rod 70. A support rod extension/contraction control unit 90d is configured to control the support rod extension/contraction mechanism 90c.

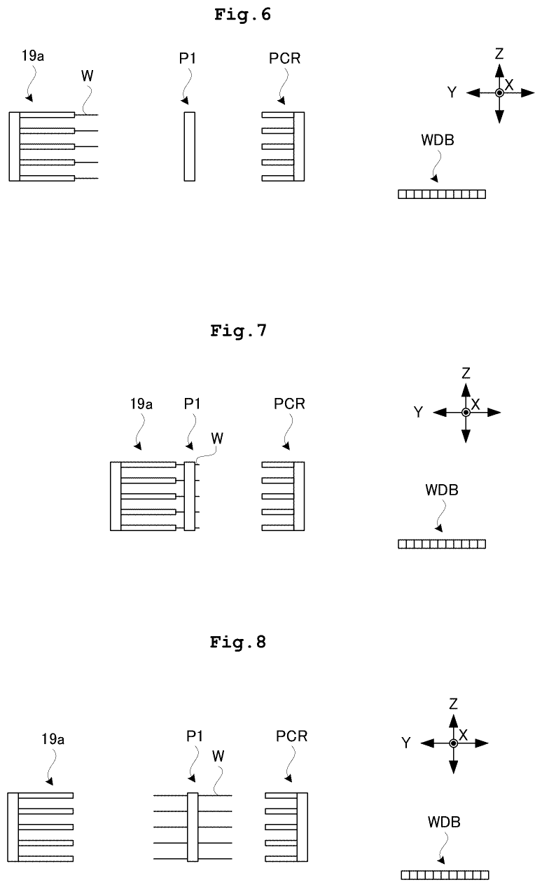

A state in which the plurality of substrates W is handed over in the transfer block 7 will be described with reference to FIGS. 6 to 16. FIG. 6 illustrates a state in which the plurality of substrates W is gripped by the collective transfer hand 71 of the collective transfer mechanism 19 in the supply block 5. The arrangement pitch of the substrates W at this time is a full pitch. This arrangement pitch is the same as the arrangement pitch when the plurality of substrates W is stored in the carrier C. Thereafter, as illustrated in FIG. 7, the collective transfer mechanism 19 transfers the plurality of gripped substrates W to the forward substrate handover position Pl in the transfer block 7. A path capable of collectively holding 25 substrates W is provided at the forward substrate handover position P1. FIG. 8 illustrates a state in which the plurality of substrates W is delivered to the forward substrate handover position P1 by the collective transfer mechanism 19.

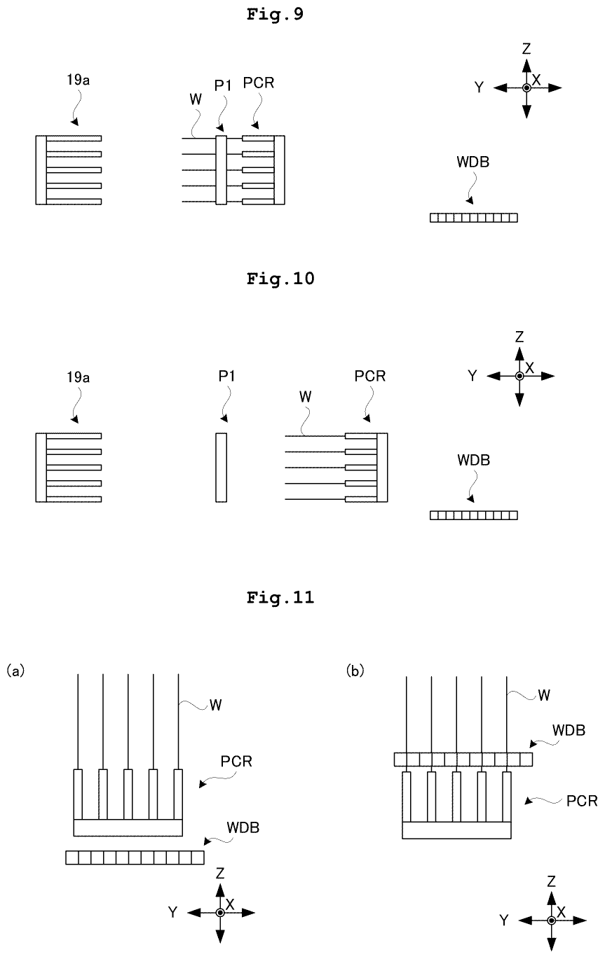

FIG. 9 illustrates a state in which the first attitude changing mechanism PCR receives the plurality of substrates W from the path at the forward substrate handover position P1. Then, FIG. 10 illustrates a state when the first attitude changing mechanism PCR moves in a direction away from the forward substrate handover position P1 in the width direction (Y direction) from the state of FIG. 9. As described above, when the first attitude changing mechanism PCR is separated from the forward substrate handover position P1 in a state of holding the plurality of substrates W, the hand base 69a of the first attitude changing mechanism PCR can rotate by 90°.

When the hand base 69a rotates 90°, the batch hand and the plurality of substrates W rotate 90° as illustrated in FIG. 11(a) accordingly. Thus, the attitude of the plurality of substrates W in the horizontal attitude becomes the vertical attitude. The support rod 70 of the substrate pickup mechanism WDB at this time is located below the batch hand of the first attitude changing mechanism PCR.

FIG. 11(b) illustrates a state when the support 70a in the substrate pickup mechanism WDB rises. When the support 70a rises from the state of FIG. 11(a), the pair of support rods 70 also rises accordingly. The separation distance of the support rod 70 in the front-rear direction (X direction) is sufficiently larger than the width of the clamping hands 69 included in the first attitude changing mechanism PCR. Therefore, the clamping hands 69 pass through the gap between the pair of support rods 70 and does not collide with the support rods 70. However, the separation distance of the support rod 70 in the front-rear direction (X direction) is sufficiently smaller than the diameter of the substrate W. Therefore, the pair of support rods 70 through which the clamping hands 69 have passed abuts on different end portions of the plurality of substrates W. The peripheral edge of the substrate W at this time is fitted into the grooves 70c provided in the support rod 70.

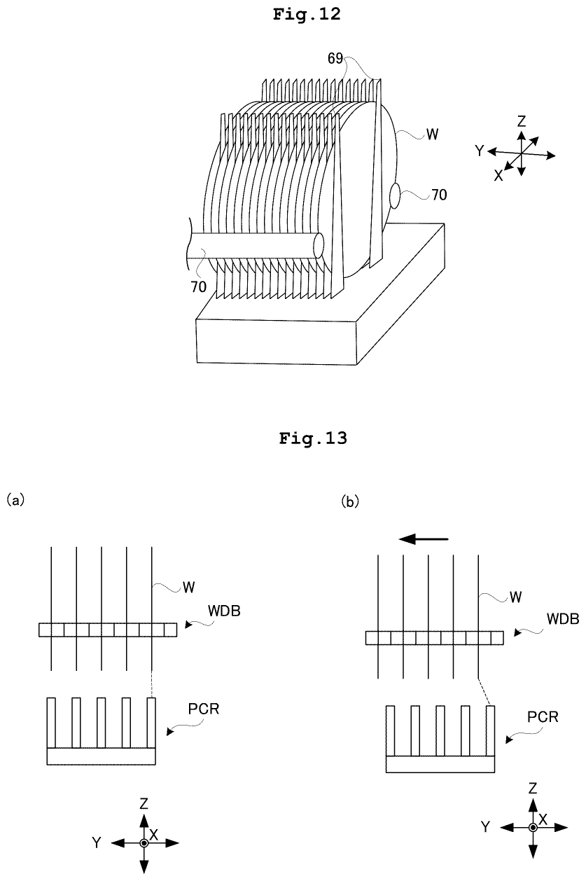

FIG. 12 illustrates a state in which the plurality of substrates W in the vertical attitude supported by the clamping hands 69 included in the first attitude changing mechanism PCR abuts on the pair of support rods 70. If the state of the clamping hands 69 that has been in the clamped state at this time is set to the released state, the plurality of substrates W is collectively transferred from the first attitude changing mechanism PCR to the substrate pickup mechanism WDB.

FIG. 13(a) illustrates a state when the support 70a in the substrate pickup mechanism WDB further rises from the state of FIG. 12. Considering that the first attitude changing mechanism PCR passes the plurality of substrates W at the arrangement pitch of the full pitch to the substrate pickup mechanism WDB, the plurality of substrates W is arranged at the full pitch on the pair of support rods 70. Since the pair of support rods 70 in the substrate pickup mechanism WDB is provided with 50 grooves 70c at the half pitch, the grooves 70c into which the substrates W are fitted and the empty grooves 70c having no substrate W are alternately arranged in the pair of support rods 70.

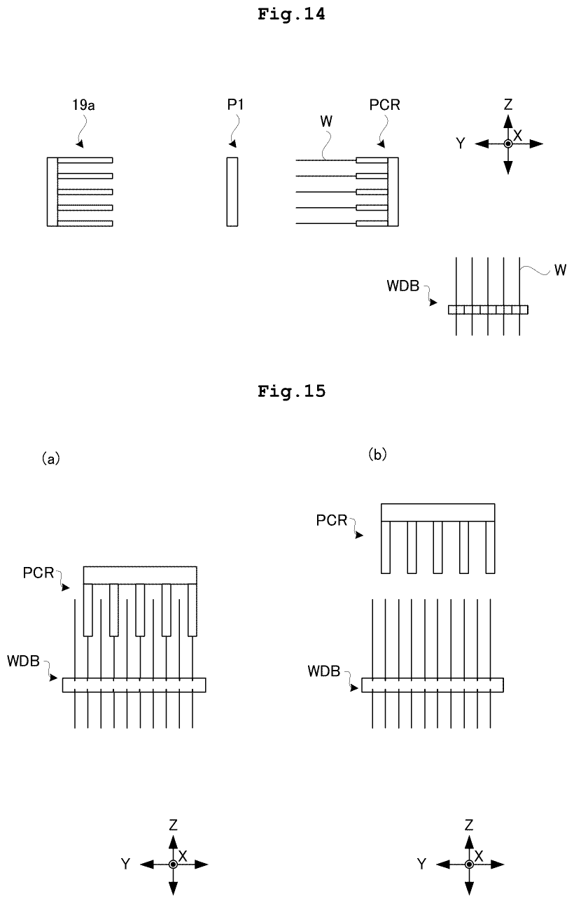

FIG. 13(b) illustrates a state where the pair of support rods 70 extends from the state of FIG. 13(a) by the distance corresponding to the half pitch with respect to the support 70a in the substrate pickup mechanism WDB. By performing such an operation, the grooves 70c provided in the pair of support rods 70 and the clamping hands 69 included in the first attitude changing mechanism PCR are shifted by the distance corresponding to the half pitch. In this state, the clamping hands 69 included in the first attitude changing mechanism PCR return to the state illustrated in FIG. 6 by moving in the width direction (Y direction) and rotating by 90°. Then, the support 70a in the substrate pickup mechanism WDB returns to the position illustrated in FIG. 6 while supporting the plurality of substrates W in the vertical attitude. Then, the collective transfer mechanism 19 takes out the plurality of substrates W from the carrier C different from the carrier C storing the plurality of substrates W supported by the substrate pickup mechanism WDB, and transfers the plurality of substrates W to the forward substrate handover position P1. FIG. 14 illustrates a state in which the clamping hands 69 included in the first attitude changing mechanism PCR support the plurality of substrates W located at the forward substrate handover position P1.

When the hand base 69a in the state of FIG. 14 is rotated by 90° in the direction opposite to the rotation direction described in FIG. 11(a), the batch hand and the plurality of substrates W is rotated by −90° accordingly. Thus, the attitude of the plurality of substrates W in the horizontal attitude becomes the vertical attitude. The support rods 70 of the substrate pickup mechanism WDB at this time are positioned under the batch hand of the first attitude changing mechanism PCR while holding the plurality of substrates W.

In this state, when the support 70a included in the substrate pickup mechanism WDB rises, as illustrated in FIG. 15(a), the plurality of substrates W clamped by the clamping hands 69 included in the first attitude changing mechanism PCR is accommodated in the respective empty grooves 70c located in the support rods 70 in the substrate pickup mechanism WDB. This is because the support 70a of the substrate pickup mechanism WDB and the clamping hands 69 included in the first attitude changing mechanism PCR are shifted by the distance corresponding to the half pitch. If the state of the clamping hands 69 that has been in the clamped state at this time is set to the released state, the plurality of substrates W is collectively transferred from the first attitude changing mechanism PCR to the substrate pickup mechanism WDB.

FIG. 15(b) illustrates a state where the clamping hands 69 included in the first attitude changing mechanism PCR is moved upward from the state of FIG. 15(a) and is away from the substrate pickup mechanism WDB. As can be seen with reference to the drawing, the plurality of substrates W is arranged at the half pitch in the substrate pickup mechanism WDB. In the substrate pickup mechanism WDB, substrates W for two carriers (50 substrates W) are arranged. Such an arrangement operation of the substrates W is referred to as a batch set. The arrangement of the substrates W at this time is a face-to-back method in which the device surface on which the circuit is formed in the substrate W and the back surface of the adjacent substrate W (the back surface of the adjacent substrate W with respect to the device surface) face each other. Thereafter, the clamping hands 69 included in the first attitude changing mechanism PCR are retracted from the upper portion of the substrate pickup mechanism WDB, and return to the original position illustrated in FIG. 6.

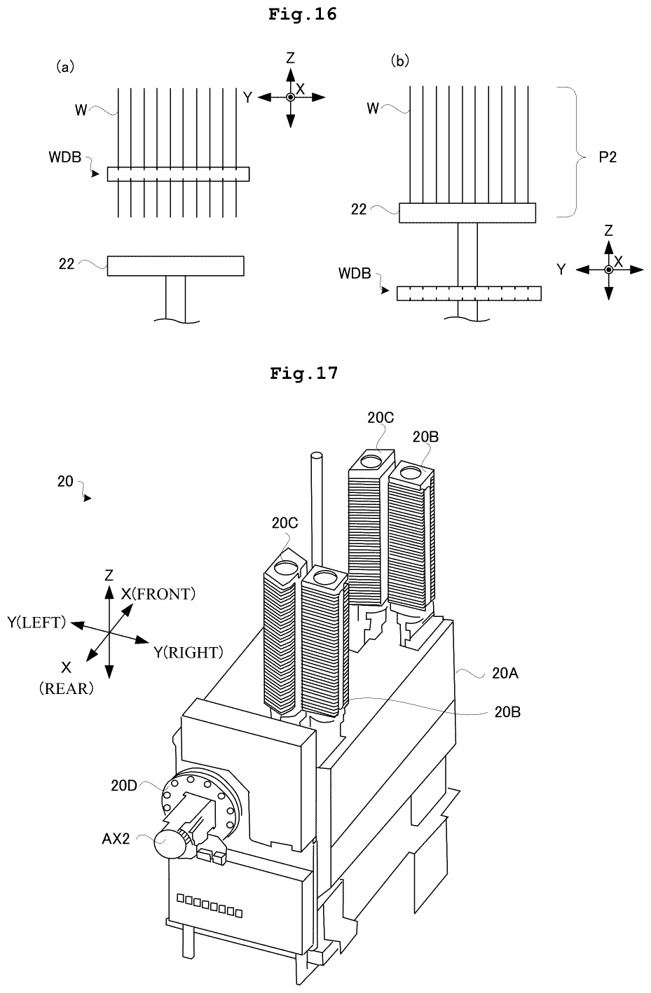

FIG. 16(a) illustrates the pusher mechanism 22 located further below the support 70a included in the substrate pickup mechanism WDB illustrated in FIG. 6. The pusher mechanism 22 includes a pusher provided with parallel grooves arranged at the half pitch on the upper surface, and the pusher can move up and down. FIG. 16(b) illustrates a state when the pusher in the pusher mechanism 22 rises. When the pusher rises from the state of FIG. 16(a), the pusher approaches the support rod 70. The separation distance in the front-rear direction (X direction) of the support rods 70 included in the substrate pickup mechanism WDB is sufficiently larger than the width of the pusher included in the pusher mechanism 22. Therefore, the pusher passes through the gap between the pair of support rods 70 and does not collide with the support rods 70. When the pusher is further raised, the plurality of substrates W accommodated in the grooves 70c of the support rods 70 is fitted into the plurality of grooves engraved in the pusher and separated from the substrate pickup mechanism WDB together with the pusher. Then, the pusher further rises, and transfers the plurality of substrates W to the vertical substrate handover position P2 set in the transfer block 7. The pusher mechanism 22 corresponds to a vertical substrate support member of the present invention. In the present example, the pusher mechanism 22 is configured to move the pusher up and down, but the pusher may be movable in the front-rear direction (X direction) in addition to the vertical direction (Z direction), and the vertical substrate handover position P2 may be provided at a position different from the substrate pickup mechanism WDB in the front-rear direction (X direction).

### 5. Processing Block

The processing block 9 performs various types of processing on the plurality of substrates W. The processing block 9 is divided into a batch processing region R1, a single wafer processing region R2, a single substrate transfer region R3, and a batch substrate transfer region R4 extending in the front-rear direction (X direction). Specifically, the batch processing region R1 is arranged on the left side in the processing block 9. The single wafer processing region R2 is arranged on the right side in the processing block 9. The single substrate transfer region R3 is disposed at a position interposed between the batch processing region R1 and the single wafer processing region R2, that is, at the center of the processing block 9. The batch substrate transfer region R4 is disposed on the leftmost side in the processing block 9.

### 5.1. Batch Processing Region

The batch processing region R1 in the processing block 9 is a rectangular region extending in the front-rear direction (X direction). One end side (front side) of the batch processing region R1 is adjacent to the transfer block 7. The other end side of the batch processing region R1 extends in a direction away from the transfer block 7 (backward side).

The batch processing region R1 includes a batch type processing unit that mainly performs batch type processing. Specifically, in the batch processing region R1, a plurality of batch processing units BPU1 to BPU3 for collectively submerging a plurality of substrates W in a direction in which the batch processing region R1 extends is arranged. The first batch processing unit BPU1 is adjacent to the transfer block 7 from the rear. The second batch processing unit BPU2 is adjacent to the first batch processing unit BPU1 from the rear. The third batch processing unit BPU3 is adjacent to the second batch processing unit BPU2 from the rear. Then, an attitude changing unit VHU that collectively changes the attitude of the plurality of substrates W in the vertical attitude at the position farthest from the transfer block 7 than the batch processing units BPU1 to BPU3 to the horizontal attitude is provided. In this manner, the first batch processing unit BPU1, the second batch processing unit BPU2, the third batch processing unit BPU3, and the attitude changing unit VHU are arranged in this order in the extending direction (X direction) of the batch processing region R1.

Specifically, the first batch processing unit BPU1 includes a batch chemical solution treatment tank CHB1 that collectively performs chemical solution treatment on a lot (a set of 50 substrates W arranged at the half pitch) and a lifter LF1 that raises and lowers the lot. The batch chemical solution treatment tank CHB1 performs acid treatment on the lot. The acid treatment may be specifically a phosphoric acid treatment, but may be a treatment using another acid. In the phosphoric acid treatment, etching treatment is performed on a plurality of substrates W constituting the lot. In the etching treatment, for example, nitride films on the surfaces of the substrates W are chemically etched.

The first batch chemical solution treatment tank CHB1 stores a chemical solution such as a phosphoric acid solution. The batch chemical solution treatment tank CHB1 supplies, for example, a chemical solution upward from below to convect the chemical solution in the tank. The lifter LF1 can be raised and lowered in the vertical direction (Z direction). Specifically, the lifter LF1 moves up and down between a treatment position corresponding to the inside of the batch chemical solution treatment tank CHB1 and a handover position corresponding to the upper side of the batch chemical solution treatment tank CHB1. The lifter LF1 holds the lot including the substrates W in the vertical direction. The lifter LF1 hands over the lot to and from the transfer mechanism WTR at the handover position. When the lifter LF1 descends from the handover position to the processing position while holding the lot, the entire regions of the substrates W are located below the liquid surface of the chemical solution. When the lifter LF1 rises from the processing position to the handover position in a state of holding the lot, the entire regions of the substrates W are located above the liquid surface of the chemical solution.

Specifically, the second batch processing unit BPU2 includes a batch chemical solution treatment tank CHB2 and a lifter LF2 that raises and lowers the lot. The batch chemical solution treatment tank CHB2 has a configuration similar to that of the batch chemical solution treatment tank CHB1 described above. That is, the batch chemical solution treatment tank CHB2 stores the chemical solution described above, and is provided with the lifter LF2 that moves up and down between the processing position and the handover position. The batch chemical solution treatment tank CHB2 performs a treatment similar to that of the batch chemical solution treatment tank CHB1 on the lot. The substrate processing apparatus 1 of this example includes a plurality of treatment tanks capable of performing the same chemical solution treatment. This is because the phosphoric acid treatment takes more time than other treatments. The phosphoric acid treatment requires a long time (for example, 60 minutes). Accordingly, in the apparatus of the present example, the acid treatment can be performed in parallel by a plurality of batch chemical solution treatment tanks. Therefore, the lot to be treated is acid-treated in either the batch chemical solution treatment tank CHB1 or the batch chemical solution treatment tank CHB2. With this configuration, the throughput of the apparatus is increased.

Specifically, the third batch processing unit BPU3 includes a batch rinse treatment tank ONB that stores a rinse solution, and a lifter LF3 that raises and lowers the lot. The batch rinse treatment tank ONB has a configuration similar to that of the batch chemical solution treatment tank CHB1 described above. That is, the batch rinse treatment tank ONB accommodates the rinse solution and is provided with the lifter LF3. Unlike other treatment tanks, the batch rinse treatment tank ONB stores pure water, and is provided for the purpose of washing off the chemical solution adhering to the plurality of substrates W. In the batch rinse treatment tank ONB, when the specific resistance of the pure water in the tank increases to a predetermined value, the chemical solution treatment ends.

As described above, the batch chemical solution treatment tank CHB1 and the batch chemical solution treatment tank CHB2 in a first embodiment are closer to the transfer block 7 than the batch rinse treatment tank ONB.

The attitude changing unit VHU includes a VHU pusher mechanism 23 that receives a lot including the substrates W in the vertical attitude from the transfer mechanism WTR, and a second attitude changing mechanism 20 that receives the lot from the VHU pusher mechanism 23 and changes the attitude of the plurality of substrates W from the vertical attitude to the horizontal attitude.

The VHU pusher mechanism 23 has a configuration similar to that of the above-described pusher mechanism 22, and includes a pusher that is moved up and down. In the pusher, 50 grooves are arranged in parallel at the half pitch. The transfer mechanism WTR can fit the substrates W one by one into each of the grooves provided in the pusher.

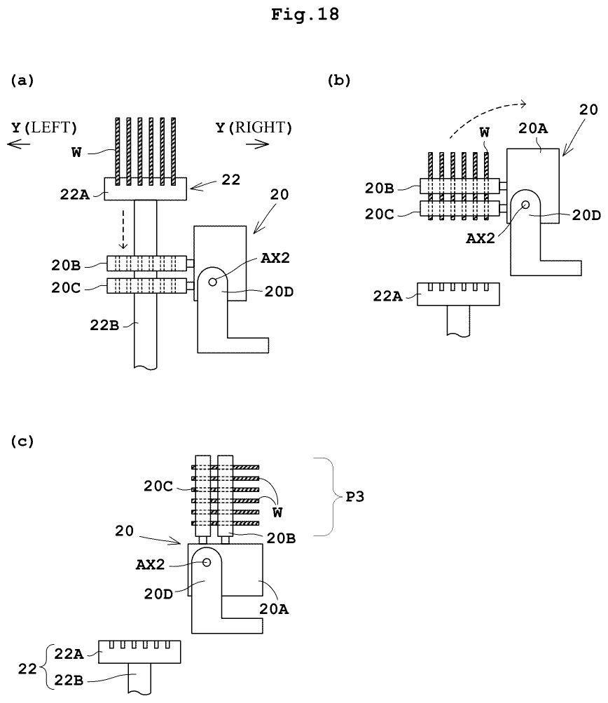

FIG. 17 illustrates the second attitude changing mechanism 20 of the present example. The second attitude changing mechanism 20 includes a pair of horizontal holding units 20B extending in the longitudinal direction (Z direction) and a pair of vertical holding units 20C extending in the same direction. The support table 20A has a support surface extending in an XY plane that supports the horizontal holding unit 20B and the vertical holding unit 20C. The rotation drive mechanism 20D is configured to rotate the support table 20A by 90°. With the rotation of the support table 20A, the horizontal holding unit 20B and the vertical holding unit 20C also rotate by 90° to become members extending in the horizontal direction. FIG. 18 is a schematic view describing the operation of the second attitude changing mechanism 20. Hereinafter, the configuration of each unit will be described with reference to FIGS. 17 and 18.

The horizontal holding unit 20B supports the plurality of substrates W in the horizontal attitude from below. That is, the horizontal holding unit 20B has a comb-shaped structure having a plurality of recesses corresponding to the substrates W to be supported. The recesses are parallel to each other and each have an elongated structure in which a peripheral edge portion of the substrate W is located. Further, the recesses are arranged at the half pitch.

The vertical holding unit 20C supports the plurality of substrates W in a vertical attitude. That is, the vertical holding unit 20C has a comb-shaped structure having a plurality of V grooves corresponding to the substrates W to be supported. The V-shaped grooves are parallel to each other and each have an elongated structure in which the peripheral edge portion of the substrate W is fitted. Further, the V grooves are arranged at a harp pitch.

The pair of horizontal holding units 20B and the pair of vertical holding units 20C extending in the vertical direction (Z direction) are provided along a virtual circle corresponding to the substrate W in a horizontal attitude so as to surround the substrate W to be held. The pair of horizontal holding units 20B is separated by the diameter of the substrate W, and holds one end of the substrate W and the other end farthest from the one end. In this manner, the pair of horizontal holding units 20B supports the substrate W in the horizontal attitude. On the other hand, the pair of vertical holding units 20C is separated by a distance shorter than the diameter of the substrate W, and supports a predetermined portion of the substrate W and a specific portion located in the vicinity of the predetermined portion. In this manner, the pair of vertical holding units 20C supports the substrate in the vertical attitude. The pair of horizontal holding units 20B are at the same position in the left-right direction (Y direction), and the pair of vertical holding units 20C are also at the same position in the left-right direction (Y direction). The pair of vertical holding units 20C is provided on the side in the direction (leftward direction) in which the support table 20A is rotated and tilted relative to the pair of horizontal holding units 20B.

The rotation drive mechanism 20D rotatably supports the support table 20A by at least 90° around a horizontal axis AX2 extending in the front-rear direction (X direction). When the support table 20A in the vertical state is rotated by 90°, the support table 20A becomes the horizontal state, and the attitude of the plurality of substrates W positioned on the support table 20A are changed from the vertical attitude to the horizontal attitude.

Operations of the second attitude changing mechanism 20 and the VHU pusher mechanism 23 will be described with reference to FIG. 18. FIG. 18(a) illustrates a state in which the transfer mechanism WTR transfers the lot to the VHU pusher mechanism 23. The support table 20A in the vertical state in the second attitude changing mechanism 20 at this time has a vertical holding unit 20C extending horizontally, and the horizontal holding unit 20B and the vertical holding unit 20C are located below the pusher of the VHU pusher mechanism 23. When the pusher of the VHU pusher mechanism 23 descends in this state, each substrate W in the vertical attitude held on the pusher is fitted into each V groove provided in the vertical holding unit 20C. In this manner, the plurality of substrates W is handed over to the second attitude changing mechanism 20 to the VHU pusher mechanism 23. FIG. 18(b) illustrates a state in which the plurality of substrates W is supported by the vertical holding unit 20C in the second attitude changing mechanism 20.

When the support table 20A is rotated by 90° from the state of FIG. 18(b), the support table 20A is in a horizontal state, and accordingly, the vertical holding unit 20C is in a state of extending in the vertical direction. Then, the substrates W fitted into the respective V-grooves of the vertical holding unit 20C rotate by 90° while maintaining the mutual positional relationship. FIG. 18(c) illustrates a state in which the plurality of substrates W is supported by the pair of horizontal holding units 20B arranged on the support table 20A in the horizontal state. Further, FIG. 18(c) illustrates a state in which the second attitude changing mechanism 20 causes the plurality of substrates W to wait at a horizontal substrate handover position P3. The horizontal substrate handover position P3 is a position at which the first robot CR1 described later receives the substrates W in the horizontal attitude.

### 5.2. Single Wafer Processing Region

The single wafer processing region R2 in the processing block 9 is a rectangular region extending in the front-rear direction (X direction). One end side (front side) of the single wafer processing region R2 is adjacent to the transfer block 7. The other end side of the single wafer processing region R2 extends in a direction away from the transfer block 7 (backward side).

The single wafer processing region R2 in the processing block 9 mainly includes a drying chamber 37 related to the drying treatment and a wet transfer mechanism WR that transfers the substrates W (horizontal attitude) before the drying treatment to each of the drying chambers 37. First, the positional relationship between the wet transfer mechanism WR and the drying chamber 37 will be described with reference to FIG. 1. As can be seen with reference to FIG. 1, in the single wafer processing region R2, a drying chamber 37 is provided at a position adjacent to the transfer block 7, and the wet transfer mechanism WR is provided at a position adjacent to the rear side of the drying chamber 37. Then, another drying chamber 37 is provided in the single wafer processing region R2. The drying chamber 37 is provided at a position adjacent to the rear side of the wet transfer mechanism WR. Therefore, the wet transfer mechanism WR is disposed at a position interposed between the two drying chambers 37. The wet transfer mechanism WR can access these drying chambers 37.

The drying chamber 37 will be described. The drying chamber 37 is a supercritical fluid chamber, and specifically dries the substrates W with carbon dioxide that has become the supercritical fluid. A substance other than carbon dioxide may be used as the supercritical fluid. The supercritical state is obtained by placing carbon dioxide under inherent critical pressure and temperature. The specific pressure is 7.38 MPa and the temperature is 31° C. In the supercritical state, the surface tension of the fluid becomes zero, so that the gas-liquid interface does not affect the circuit pattern on the substrate surface. Therefore, when the substrates W are dried with the supercritical fluid, it is possible to prevent the occurrence of what is called a pattern collapse in which the circuit pattern is collapsed on the substrates.

The configuration of the drying chamber 37 will be further described. As illustrated in FIG. 1, the drying chamber 37 includes a carry-in port 37a through which the substrate W is introduced into the chamber and a carry-out port 37b through which the substrate W is discharged out of the chamber. The carry-in port 37a is provided on a side wall facing the wet transfer mechanism WR in the drying chamber 37. The carry-out port 37b is provided on a side wall of the drying chamber 37 facing the single substrate transfer region R3. Each of the carry-in port 37a and the carry-out port 37b is provided with a shutter capable of closing a passage port of the substrates W, and each shutter closes each of the corresponding passage ports during the substrate drying treatment.

Inside the drying chamber 37, a circular support member 37c that supports the substrate W via a pin 37d on which the substrate W abuts is provided. The support member 37c is provided with three pins 37d, and these pins 37d abut on three different portions in the peripheral edge portion of the substrate W introduced into the drying chamber 37. In this manner, the substrate W is supported at three points in the drying chamber 37. When the drying chamber 37 dries the substrate W, a supercritical fluid is generated inside the chamber. The drying chamber 37 is configured to have a sufficient pressure resistance to cause the inside of the chamber to have a critical pressure.

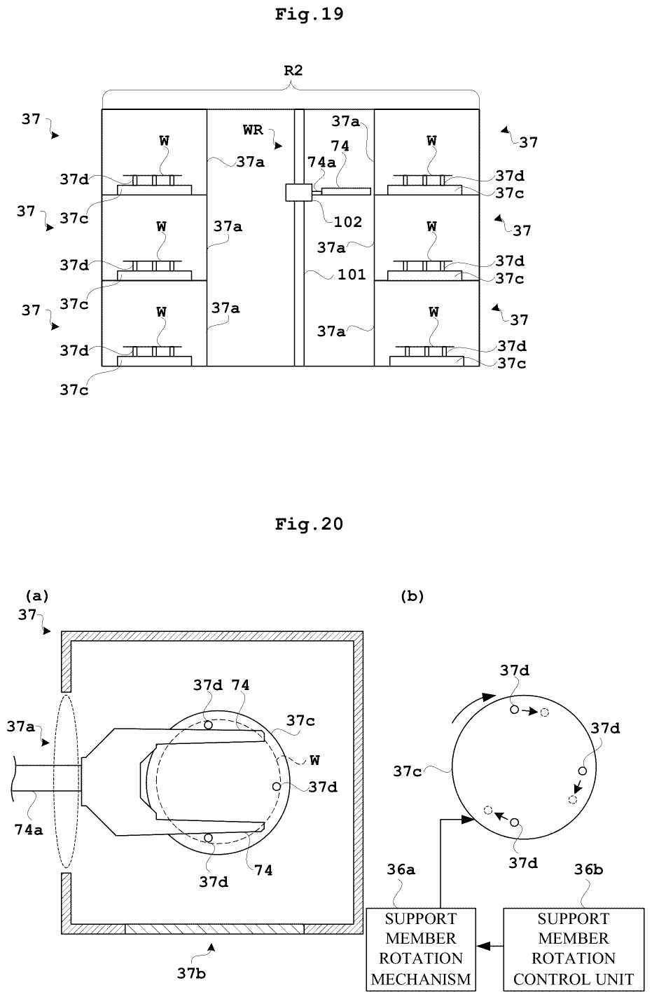

FIG. 19 is a side view of the single wafer processing region R2 as viewed from the single substrate transfer region R3 side. The single wafer processing region R2 is provided with two stacks each formed by stacking three drying chambers 37.

The wet transfer mechanism WR is provided at a position interposed between the two stacks, and can carry the substrate W into each of the drying chambers 37 constituting each stack. The substrate W is carried in through the carry-in port 37a provided in the drying chamber 37.

A wet substrate transfer region that secures a movable range of the wet transfer mechanism WR is provided between the two stacks. The wet transfer mechanism WR is configured to be movable in the transfer region.

FIG. 20(a) illustrates a state when the wet transfer mechanism WR transfers the substrate W to be dried into the drying chamber 37. As illustrated in FIG. 20, the wet transfer mechanism WR includes a pair of wet arms 74 for gripping the substrate W before the drying treatment. The wet arm 74 is configured to be capable of entering the chamber through the carry-in port 37a in the drying chamber 37 in a state of gripping the substrate W, and to pass the substrate W to the support member 37c. A wet arm base portion 74a is configured to support the pair of wet arms 74.

As can be seen with reference to FIG. 20(a), the pin 37d of the support member 37c is provided at a position avoiding the wet arm 74. Therefore, the pin 37d does not collide with the wet arm 74 that has come to pass the substrate W inside the chamber.

Note that the wet transfer mechanism WR of the wet arm 74 is provided for the purpose of carrying the substrate W before the drying treatment into the drying chamber 37. Therefore, the substrate processing apparatus 1 of the present example includes a mechanism different from the wet transfer mechanism WR for carrying out the substrate W subjected to the drying treatment from the drying chamber 37. Since the position of the pin 37d in the support member 37c is optimized for carrying in the substrate W by the wet arm 74, there is a possibility that the arm holding the substrate W collides with the pin 37d when the substrate W after the drying treatment is carried out of the chamber. As illustrated in FIG. 20(b), the apparatus of the present example includes a support member rotation mechanism 36a that rotates the support member 37c so that the substrate W can be reliably carried out of the chamber and a support member rotation control unit 36b that controls the support member rotation mechanism 36a. When the support member 37c is rotated by the support member rotation mechanism 36a, the pin 37d on the support member 37c moves around the center of the circular support member 37c. Therefore, when the substrate W is carried out of the chamber, the pin 37d can be moved to a position that does not hinder the carrying out.

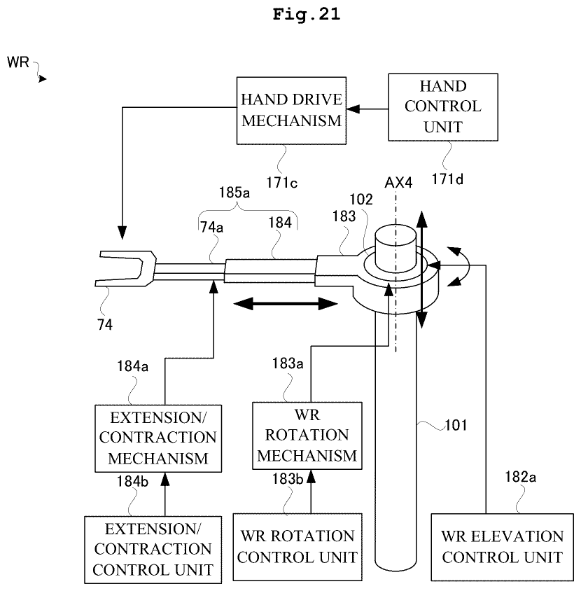

FIG. 21 is a functional block diagram illustrating a configuration of the wet transfer mechanism WR. The wet transfer mechanism WR is a mechanism that receives the substrate W before the drying treatment from the single substrate transfer region R3 described later and transfers the substrate W to the drying chamber 37. As illustrated in FIG. 21, the wet transfer mechanism WR includes WR support columns 101 extending in the vertical direction (Z direction) for supporting each mechanism. The wet transfer mechanism WR further includes a WR elevation mechanism 102 capable of vertical movement. The WR elevation mechanism 102 is liftably supported by a WR support column 101. The WR elevation mechanism 102 rotatably supports a WR rotating member 183. The WR rotating member 183 is rotatable about a rotation axis AX4 parallel to the extending direction (Z direction) of the WR support column 101 in a state of being supported by the WR elevation mechanism 102. The rotation axis AX4 is a virtual straight line located at the center of the WR support column 101.

The wet transfer mechanism WR supports an extendable WR arm 185a. The WR arm 185a includes a first arm 184 connected to the WR rotating member 183 and a base portion (second arm) 74a connected to the first arm 184. A connecting portion of the first arm 184 in the WR rotating member 183 is a protruding portion extending in a direction away from the rotation center of the WR rotating member 183, and the first arm 184 is configured to extend the protruding portion. The wet arm base portion 74a is configured to extend the first arm 184. The WR rotating member 183 supports the first arm 184 so that the first arm 184 is movable in the extending direction of the first arm 184, and the first arm 184 supports the wet arm base portion 74a so that the wet arm base portion 74a is movable in the extending direction of the wet arm base portion 74a. Therefore, the WR arm 185a is extendable in the extending direction of the first arm 184 and the wet arm base portion 74a.

Hereinafter, each mechanism provided in the wet transfer mechanism WR and a control unit that controls these mechanisms will be described. A WR elevation control unit 182a is configured to control the WR elevation mechanism 102. A WR rotation mechanism 183a is a mechanism that rotates the WR rotating member 183 with respect to the WR elevation mechanism 102, and a WR rotation control unit 183b is configured to control the WR rotation mechanism 183a. An extension/contraction mechanism 184a is configured to extend/contract the WR arm 185a in the extending direction, and an extension/contraction control unit 184b is configured to control the extension/contraction mechanism 184a. The WR hand drive mechanism 171c is a mechanism that drives the wet arm 74 to grip only one substrate W in a horizontal attitude or release the gripping of the substrate W. A hand control unit 171d is configured to control the WR hand drive mechanism 171c.

As described above, the wet transfer mechanism WR of the present example simplifies the above-described collective transfer mechanism 19, and does not include the rail 87, the direction changing member 86, each mechanism related to the operation, and each control unit. The present invention is not limited to this configuration, and each member, each mechanism related thereto, and each control unit may be provided.

The wet transfer mechanism WR is configured to be accessible to any of the six drying chambers 37 constituting the stack of chambers provided on the left and right sides thereof, and to be capable of carrying the substrate W to be dried into any of the drying chambers 37.

### 5.3. Single Substrate Transfer Region

The single substrate transfer region R3 in the processing block 9 is a rectangular region extending in the front-rear direction (X direction). The single substrate transfer region R3 is interposed between the batch processing region R1 and the single wafer processing region R2, and has one end adjacent to the transfer block 7 and the other end extending in a direction away from the transfer block 7.

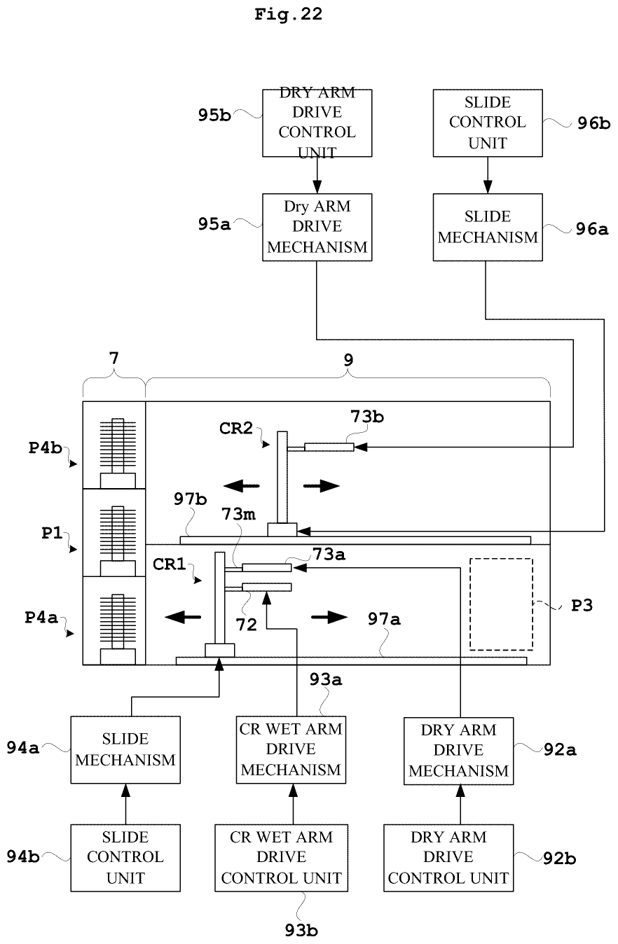

As illustrated in FIG. 22, the single substrate transfer region R3 includes a first robot CR1 that can access the second attitude changing mechanism 20 at the horizontal substrate handover position P3 provided in the batch processing region R1, and a second robot CR2 provided above the first robot CR1.

The single substrate transfer region R3 is divided into upper and lower parts by a partition wall. A first robot CR1 is provided in the lower section, and a second robot is provided in the upper section. As described above, since the first robot CR1 and the second robot CR2 are provided in different sections, one robot does not prevent the other robot from transferring the substrate.

A configuration of a lower section of the single substrate transfer region R3 will be described. The section faces the second attitude changing mechanism 20 at the horizontal substrate handover position P3 in the batch processing region R1, faces the lowermost drying chamber 37 (more specifically, the carry-out port 37b of the chamber) among the drying chambers 37 constituting the stacks, faces the wet transfer mechanism WR, and faces the return substrate handover position (more precisely, the first return substrate handover position P4a). The first robot CR1 transfers the substrate W between the second attitude changing mechanism 20 at the horizontal substrate handover position P3, the lowermost drying chamber 37, the wet transfer mechanism WR, and the first return substrate handover position P4a in the transfer block 7. Similarly to the forward substrate handover position P1, the first return substrate handover position P4a is a path capable of holding the plurality of substrates W at the full pitch. The first return substrate handover position P4a is located below the forward substrate handover position P1.

The first robot CR1 includes a CR wet arm 72 that supports the substrate W (horizontal attitude) before the drying treatment, and a dry arm 73a that grips the substrate W (horizontal attitude) after the drying treatment. The CR wet arm 72 and the dry arm 73a are mounted on a single robot, and the CR wet arm 72 is always located below the dry arm 73a. With this configuration, the CR wet arm 72 supporting the wet substrate W does not drip liquid toward the dry arm 73a, and the dry state of the dry arm 73a can be reliably maintained. The first robot CR1 uses the CR wet arm 72 when transferring the substrate W from the second attitude changing mechanism 20 at the horizontal substrate handover position P3 to the wet transfer mechanism WR. The first robot CR1 uses the dry arm 73a when transferring the substrate W from the lowermost drying chamber 37 to the first return substrate handover position P4a.

A robot guide rail 97a capable of guiding the first robot CR1 is provided on the floor surface of the lower section of the single substrate transfer region R3. Since the rail extends in the front-rear direction (X direction), the first robot CR1 can also move in the front-rear direction (X direction) along the rail.

Hereinafter, each mechanism and each control unit related to the first robot CR1 will be described. A dry arm drive mechanism 92a is a mechanism that drives the dry arm 73a, and the dry arm drive control unit 92b controls the dry arm drive mechanism 92a. A CR wet arm drive mechanism 93a is a mechanism that drives the CR wet arm 72, and a CR wet arm drive control unit 93b controls the CR wet arm drive mechanism 93a. A slide mechanism 94a is a mechanism that moves the first robot CR1 along the robot guide rail 97a, and the slide control unit 94b controls the slide mechanism 94a.

A configuration of an upper section of the single substrate transfer region R3 will be described. The section faces the uppermost and middle drying chambers 37 (more specifically, the carry-out port 37b of the chamber) among the drying chambers 37 constituting the stacks, and faces the return substrate handover position (more precisely, a second return substrate handover position P4b). The second robot CR2 transfers the substrate W between the drying chamber 37 located in the uppermost layer or the middle layer and the second return substrate handover position P4b in the transfer block 7. Similarly to the forward substrate handover position P1, the second return substrate handover position P4b is a path capable of holding the plurality of substrates W at the full pitch. The second return substrate handover position P4b is located above the forward substrate handover position P1.

The second robot CR2 includes a dry arm 73b that grips the substrate W (horizontal attitude) after the drying treatment. A robot guide rail 97b capable of guiding the second robot CR2 is provided on a floor surface of an upper section of the single substrate transfer region R3. Since the rail extends in the front-rear direction (X direction), the second robot CR2 can also move in the front-rear direction (X direction) along the rail.

Hereinafter, each mechanism and each control unit related to the second robot CR2 will be described. A dry arm drive mechanism 95a is a mechanism that drives the dry arm 73b, and the dry arm drive control unit 95b controls the dry arm drive mechanism 95a. A slide mechanism 96a is a mechanism that moves the second robot CR2 along the robot guide rail 97b, and the slide control unit 96b controls the slide mechanism 96a.

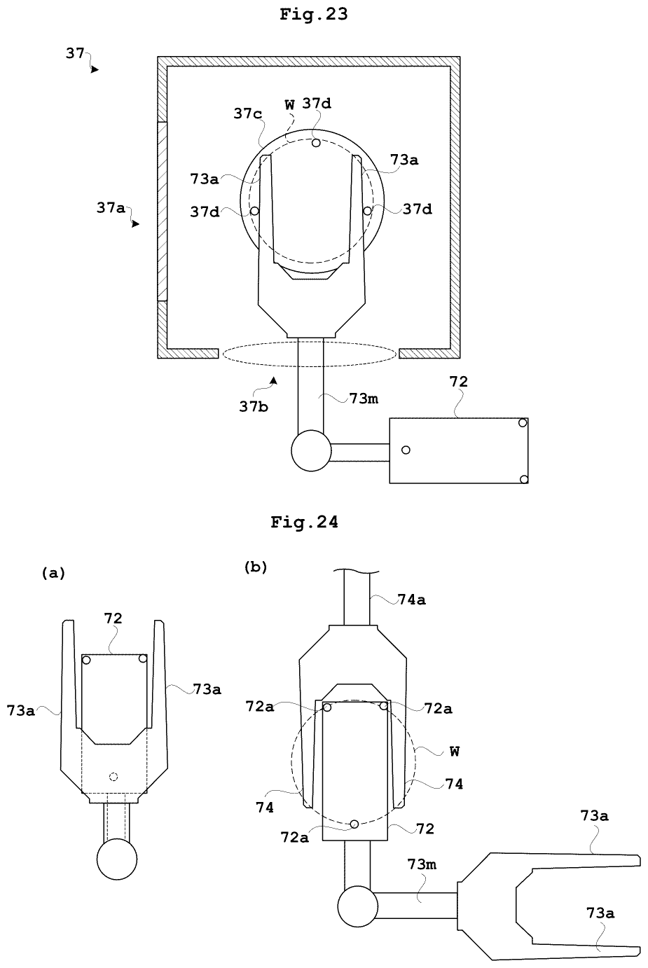

FIG. 23 illustrates a state where the first robot CR1 takes out the substrate W subjected to the drying treatment from the lowermost drying chamber 37. The dry arm 73a is capable of entering the chamber through the carry-out port 37b in the drying chamber 37, and is configured to acquire the substrate W from the support member 37c. A base portion 73m is configured to support the pair of dry arms 73a.

As can be seen with reference to FIG. 23, the pin 37d of the support member 37c is provided at a position avoiding the dry arm 73a. Therefore, the pin 37d does not collide with the dry arm 73a that has come to acquire the substrate W inside the chamber. Note that, since the pin 37d can be rotationally moved by the support member rotation mechanism 36a, when the pin 37d is at a position where the pin collides with the dry arm 73a, the position of the pin 37d can be appropriately changed before the dry arm 73a is introduced into the carry-out port 37b so that the pin 37d does not collide with the dry arm 73a.

FIG. 23 also illustrates the CR wet arm 72 provided in the first robot CR1. The CR wet arm 72 can be rotationally moved with respect to the dry arm 73a by the CR wet arm drive mechanism 93a. In FIG. 23, the CR wet arm 72 is rotated by 90° with respect to the dry arm 73a so as not to hinder the transfer of the substrate W by the dry arm 73a.

FIG. 24(a) illustrates a case where the CR wet arm 72 provided in the first robot CR1 is at a position overlapping the dry arm 73a. The dry arm 73a grips both ends of the substrate W, whereas the CR wet arm 72 has a single plate-like configuration. Therefore, the substrate W is transferred in a state of being mounted on the CR wet arm 72.

FIG. 24(b) illustrates a state in which the first robot CR1 transfers the substrate W to be dried to the wet transfer mechanism WR. The CR wet arm 72 is provided with tabs 72a at three positions of a plate-shaped member. The tabs 72a are configured to temporarily fix the peripheral edge portion of the substrate W when the CR wet arm 72 transfers the substrate W. When the substrate W is handed over from the first robot CR1 to the wet transfer mechanism WR, the CR wet arm 72 holding the substrate W is arranged in a space surrounded by the pair of wet arms 74. In this state, the substrate W is gripped by the wet transfer mechanism WR, and the holding of the substrate W by the CR wet arm 72 is released. Then, the substrate W is handed over from the first robot CR1 to the wet transfer mechanism WR.

FIG. 24(b) also illustrates the dry arm 73a provided in the first robot CR1. The dry arm 73a can be rotationally moved with respect to the CR wet arm 72 by the dry arm drive mechanism 92a. In FIG. 24(b), the dry arm 73a is rotated by 90° with respect to the CR wet arm 72 so as not to hinder the transfer of the substrate W by the CR wet arm 72.

FIG. 23 illustrates the first robot CR1, and thus includes the CR wet arm 72. When the second robot CR2 carries out the dried substrate W from the uppermost or middle drying chamber 37, the second robot CR2 not including the CR wet arm 72 carries out the dried substrate W from the drying chamber 37 using the dry arm 73b. That is, the second robot CR2 is different from the first robot CR1 in that the CR wet arm 72 is not provided, but the operation of the dry arm 73b is similar to that of the dry arm 73a in the first robot CR1. Further, the pins 37d in the uppermost or middle drying chamber 37 rotates to avoid the dry arms 73b is similar to that in the lowermost drying chamber 37.

### 5.4. Batch Substrate Transfer Region

The batch substrate transfer region R4 in the processing block 9 is a rectangular region extending in the front-rear direction (X direction). The batch substrate transfer region R4 is provided along the outer edge of the batch processing region R1, and has one end side extending to the transfer block 7 and the other end side extending in a direction away from the transfer block 7.

The batch substrate transfer region R4 is provided with the transfer mechanism WTR for collectively transferring the plurality of substrates W (vertical attitude). The transfer mechanism WTR collectively transfers the plurality of substrates W (lot) arranged at the half pitch between the vertical substrate handover position P2 defined in the transfer block 7, each of the batch processing units BPU1 to BPU3, and the attitude changing unit VHU. The transfer mechanism WTR is configured to be able to reciprocate in the front-rear direction (X direction) across the transfer block 7 and the processing block 9. That is, the transfer mechanism WTR can move not only to the processing block 9 but also to the vertical substrate handover position P2 in the transfer block 7. The transfer mechanism WTR corresponds to a batch substrate transfer mechanism of the present invention.

The transfer mechanism WTR includes a pair of hands 23 for gripping the lot. The pair of hands 23 includes, for example, a rotation shaft oriented in the width direction (Y direction), and swings around the rotation shaft. The pair of hands 23 holds both ends of the plurality of substrates W constituting the lot. The transfer mechanism WTR transfers the lot to and from the vertical substrate handover position P2 in the transfer block 7, the lifters LF1 to LF3 belonging to the batch processing units BPU1 to BPU3, and the VHU pusher 23a in the attitude changing unit VHU.

The substrate processing apparatus 1 of the present example includes, in addition to the above-described units, a central processing unit (CPU) 89a that controls each mechanism and each processing unit, and a storage unit 89b that stores various upper portions necessary for a processing process such as programs and setting values. Note that the specific configuration of the CPU is not particularly limited. One CPU may be provided in the entire apparatus, or one or more CPUs may be provided in each block. The same applies to the storage unit 89b. Examples of the control performed by the CPU include control related to operations of the collective transfer mechanism 19, the first attitude changing mechanism PCR, the substrate pickup mechanism WDB, the batch processing units BPU1 to BPU3, the attitude changing unit VHU, the wet transfer mechanism WR, the first robot CR1, the second robot CR2, the transfer mechanism WTR, and the like.

### Flow of Substrate Processing

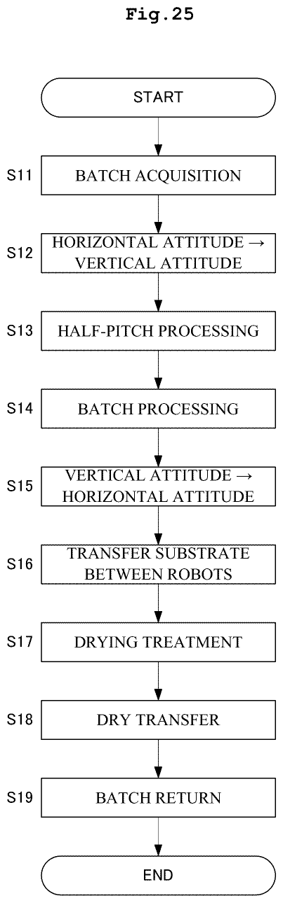

FIG. 25 is a flowchart describing the flow of the substrate processing of the present example. In the substrate processing of the present example, for example, each processing related to surface etching of the substrate W in the semiconductor device manufacturing process is performed. Hereinafter, the flow of the substrate processing will be specifically described along the flowchart.
Step S11: The carrier C that stores the substrate W to be processed is set in the carrier holding unit 11. The plurality of substrates W is taken out from the carrier C by the collective transfer mechanism 19 and transferred to the forward substrate handover position P1.
Step S12: The plurality of substrates W is handed over to the first attitude changing mechanism PCR. The first attitude changing mechanism PCR changes the attitude of the substrate W from the horizontal attitude to the vertical attitude.
Step S13: The plurality of substrates W whose attitude has been changed to the vertical attitude is handed over to the pusher mechanism 22. The pusher mechanism 22 executes batch assembly by changing the arrangement pitch of the substrates W having the full pitch to the half pitch in cooperation with the substrate pickup mechanism WDB.
Step S14: The plurality of substrates W transferred to the vertical substrate handover position P2 is transferred to the batch processing region R1 by the substrate transfer mechanism WTR. The plurality of substrates W is subjected to various liquid treatments in a state of forming a lot.
Step S15: The plurality of substrates W transferred to the attitude changing unit VHU by the substrate transfer mechanism WTR is handed over to the second attitude changing mechanism 20. The second attitude changing mechanism 20 changes the attitude of the substrates W from the vertical attitude to the horizontal attitude, and causes the plurality of substrates W to wait at the horizontal substrate handover position P3.

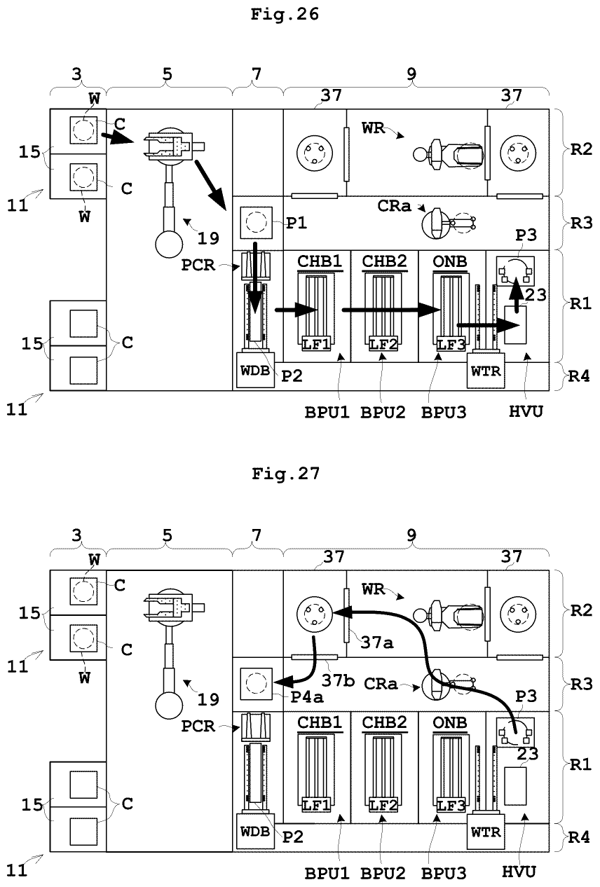

FIG. 26 illustrates substrate transfer in steps S11 to S15. In each process illustrated in FIG. 26, the plurality of substrates W is collectively transferred.
Step S16: The first robot CR1 in the single substrate transfer region R3 receives one substrate W from the second attitude changing mechanism 20 using the CR wet arm 72, and passes the substrate W to the wet transfer mechanism WR in the single wafer processing region R2 (see FIG. 24(b)).
Step S17: The wet transfer mechanism WR transfers the substrate W to be dried into any one of the empty drying chambers 37 (drying chamber 37 not performing drying treatment) located in the uppermost layer, the middle layer, and the lowermost layer. The drying chamber 37 performs a drying treatment on the carried substrate W.
Step S18: The substrate W after the drying treatment is carried out from the chamber by the first robot CR1 or the second robot CR2. Specifically, the substrate W in the drying chamber 37 located at the lowermost layer is transferred to the first return substrate handover position P4a by the dry arm 73a of the first robot CR1. Further, the substrates W in the drying chambers 37 located in the uppermost layer and the middle layer are transferred to the second return substrate handover position P4b by the second robot CR2.

FIG. 27 illustrates substrate transfer in steps S16 to S18. In each process illustrated in FIG. 27, the substrates W are transferred one by one. Note that FIG. 27 illustrates a state in which the substrate W in the drying chamber 37 located at the lowermost layer is transferred to the first return substrate handover position P4a.
Step S19: When the predetermined number of substrates W are filled in the path arranged at the first return substrate handover position P4a or the second return substrate handover position P4b by repeating the above-described steps S16 to 18 several times, the substrates W of the path are held by the collective transfer mechanism 19 and returned to the original carrier C.

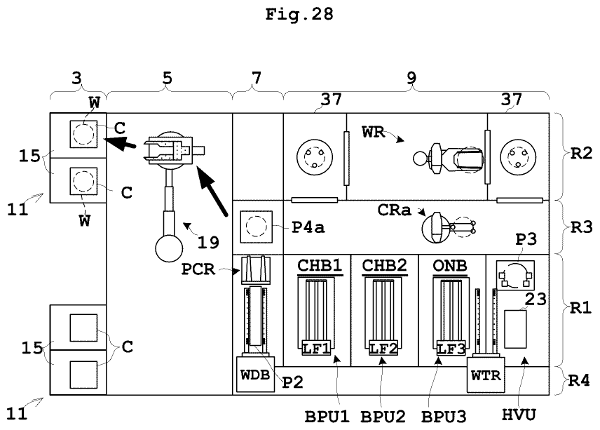

FIG. 28 illustrates a state in which the plurality of substrates W is collectively transferred in step S19. Note that FIG. 28 illustrates a state in which the plurality of substrates W is transferred from the first return substrate handover position P4a. In this manner, the substrate processing by the substrate processing apparatus 1 according to the present example ends.

As described above, according to the present example, the substrates W are collectively taken out from the carrier C storing the plurality of substrates W in the horizontal attitude, and the attitude of the substrates W is collectively changed from the horizontal attitude to the vertical attitude by the first attitude changing mechanism PCR. Then, the plurality of substrates W is subjected to batch processing in the batch processing region R1 in a state where the vertical attitude is maintained, and the attitude of the substrates W is collectively changed from the vertical attitude to the horizontal attitude by the second attitude changing mechanism 20. Thereafter, the substrate W is subjected to the single wafer processing by the single wafer processing region R2 in a state where the horizontal attitude is maintained. The single wafer processing is specifically substrate drying treatment. The single wafer processing region R2 of the present invention includes a wet transfer mechanism WR that transfers the wet substrate W to be subjected to the drying treatment to the drying chamber 37, and includes the first robot CR1 and the second robot CR2 that transfer the dried substrate W after the drying treatment to the drying chamber 37. With such a configuration, since the carrying in and carrying out of the substrate W into and from the drying chamber 37 can be implemented by different mechanisms, the transfer of the substrate is not congested around the drying chamber 37. According to the present invention, since the drying chambers 37 are stacked in the vertical direction and the substrate is smoothly transferred around the drying chambers 37, it is possible to provide a substrate processing apparatus in which many drying chambers are mounted in the same floor area as that of the conventional apparatus.

### Second Embodiment

Subsequently, a substrate processing apparatus 2 according to a second embodiment will be described. The substrate processing apparatus 2 according to the present example is different from the apparatus according to the first embodiment in that a third robot CR3 and a fourth robot CR4 are provided in a lower section of the single substrate transfer region R3. A specific device configuration will be described later.

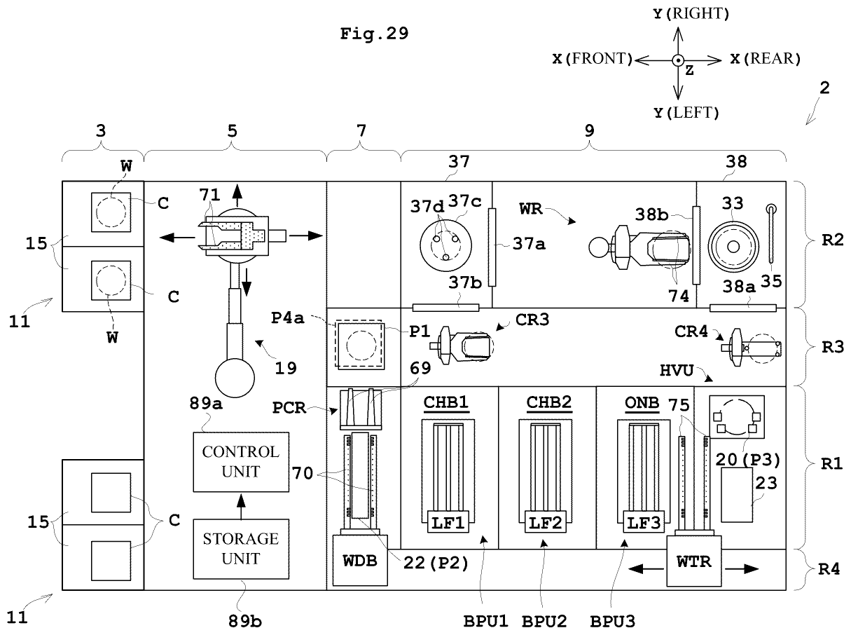

FIG. 29 illustrates an overall configuration of the substrate processing apparatus 2. The carry-in/out block 3, the supply block 5, and the transfer block 7 in the substrate processing apparatus 2 are similar to those in the apparatus of the first embodiment. Further, the configuration of the batch processing region RI and the batch substrate transfer region R4 in the processing block 9 of the present example is also similar to that of the first embodiment.

### Single Substrate Processing Region

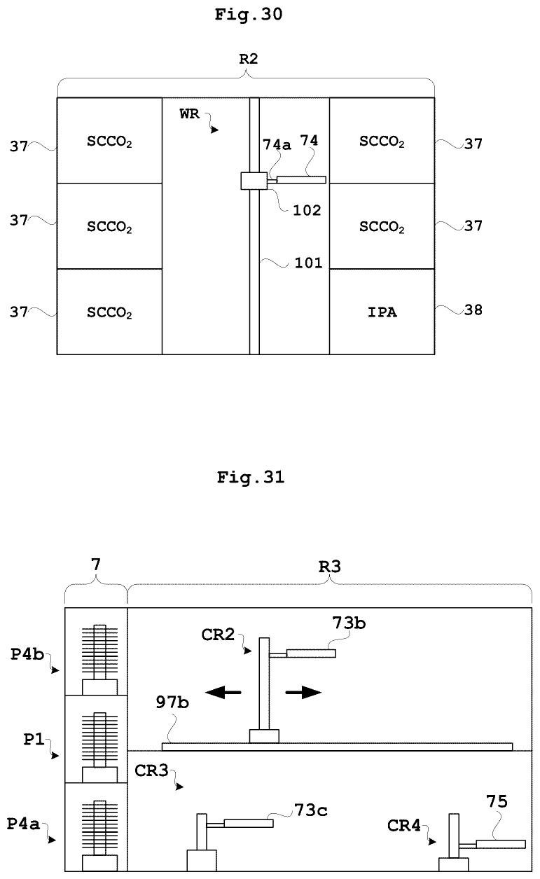

FIG. 30 is a side view illustrating the single wafer processing region R2 of the present example. In the single wafer processing region R2 of the present example, six single wafer type substrate processing chambers are provided. In the present example, a stack is formed by stacking three substrate processing chambers, two stacks are provided, and a wet transfer mechanism WR is provided at a position interposed between the two stacks, which are similar to those in the first embodiment.

In the stack provided in the single wafer processing region R2 of the present example, the stack located at a position away from the transfer block 7 is provided with a substrate drying pretreatment chamber 38 that executes a pretreatment of drying treatment, unlike the first embodiment. The substrate drying pretreatment chamber 38 supplies isopropyl alcohol (IPA) to the surface of the substrate to be subjected to the drying treatment to execute the pretreatment process of the drying treatment. The liquid to be supplied is not limited to IPA, and may be a mixed liquid of IPA and water. The substrate drying pretreatment chamber 38 is provided in the lowermost layer of the stack. In the plan view of FIG. 29, the single wafer processing chamber located at the lowermost layer of the stack in the single wafer processing region R2 is described. Therefore, the wet transfer mechanism WR in FIG. 29 is at a position interposed between the drying chamber 37 provided on the transfer block 7 side and the substrate drying pretreatment chamber 38 provided at a position away from the transfer block 7.

The substrate drying pretreatment chamber 38 is at the same position as the second attitude changing mechanism 20 in the front-rear direction (X direction).

Similarly to the drying chamber 37, the substrate drying pretreatment chamber 38 includes a carry-in port 38a and a carry-out port 38b each including a shutter. During the drying pretreatment, the shutters of the carry-in port 38a and the carry-out port 38b are closed for the purpose of preventing the IPA in the chamber from scattering out of the chamber. Unlike the drying chamber 37, the substrate drying pretreatment chamber 38 does not necessarily have pressure resistance.

The substrate drying pretreatment chamber 38 includes a rotation processing unit 33 that rotates the substrate W in the horizontal attitude, and a nozzle 35 that supplies a treatment liquid (IPA) toward the substrate W. The rotation processing unit 33 rotationally drives the substrate W in an XY plane (horizontal plane). The nozzle 35 is turnable between a standby position away from the rotation processing unit 33 and a supply position located above the rotation processing unit 33.

### Single Substrate Transfer Region

FIG. 31 is a side view illustrating the single substrate transfer region R3 of the present example. The single substrate transfer region R3 of the present example is provided with an upper section and a lower section formed by a partition wall, and the upper section has the same configuration as that of the first embodiment. That is, the section is provided with the second robot CR2 that receives the dried substrate from the drying chamber 37 located in the uppermost layer and the middle layer among the stacks of the chambers provided in the single wafer processing region R2, and transfers the dried substrate to the second return substrate handover position P4b. The second robot CR2 includes a dry arm 73b that is movable in the front-rear direction (X direction) and grips the substrate W after the drying treatment.

Two robots are provided in a lower region of the single substrate transfer region R3 of the present example. That is, the third robot CR3 that transfers the substrate W subjected to the drying treatment and the fourth robot CR4 that transfers the wet substrate W to be subjected to the drying treatment are provided in the lower region. The third robot CR3 is provided with a dry arm 73c similar to the dry arm 73b of the second robot CR2, and the fourth robot CR4 is provided with a CR wet arm 75 similar to the CR wet arm 72 of the first robot CR1 of the first embodiment.

The third robot CR3 is provided closer to the transfer block 7 than the fourth robot CR4, and transfers the substrate W (horizontal attitude) after the drying treatment from the drying chamber 37 adjacent to the transfer block 7 in the single wafer processing region R2 to the first return substrate handover position P4a. One drying chamber 37 adjacent to the transfer block 7 is provided in each of the uppermost layer, the middle layer, and the lowermost layer, and the third robot CR3 can access the drying chamber 37 located in the lowermost layer among them. At the first return substrate handover position P4a, the substrates W are arranged at full pitch intervals in the vertical direction (Z direction). Therefore, the dry arm 73c included in the third robot CR3 can move up and down so that the substrate W can be stacked at the first return substrate handover position P4a.

The fourth robot CR4 is provided at a position farther from the transfer block 7 than the third robot CR3. The fourth robot CR4 can receive the substrate W (horizontal attitude) from the horizontal substrate handover position P3 in the batch processing region R1, and carry the substrate W (horizontal attitude) into the substrate drying pretreatment chamber 38 from the carry-in port 38a of the substrate drying pretreatment chamber 38 in the single wafer processing region R2. At the horizontal substrate handover position P3, the substrates W are arranged at half-pitch intervals in the vertical direction (Z direction). Therefore, the CR wet arm 75 of the fourth robot CR4 can be moved up and down so as to be able to acquire the substrate W stacked at the horizontal substrate handover position P3.

The fourth robot CR4 is at the same position as the substrate drying pretreatment chamber 38 and the second attitude changing mechanism 20 in the front-rear direction (X direction). Therefore, the fourth robot CR4 faces the substrate drying pretreatment chamber 38 and also faces the second attitude changing mechanism 20. As described above, the fourth robot CR4 is disposed at a position suitable for transferring the substrate W between the second attitude changing mechanism 20 and the substrate drying pretreatment chamber 38.

The third robot CR3, the wet transfer mechanism WR, and the fourth robot CR4 are at different positions in the front-rear direction (X direction).

It is sufficient if the third robot CR3 can access one of the five drying chambers 37 provided in the single wafer processing region R2, and the third robot CR3 does not necessarily move in the front-rear direction (X direction). Therefore, the apparatus of the present example can have a configuration in which the mechanism for horizontally moving the third robot CR3 and the control unit are omitted. Similarly, it is sufficient if the fourth robot CR4 can access the substrate drying pretreatment chamber 38 provided once in the single wafer processing region R2, and the fourth robot CR4 does not necessarily move in the front-rear direction (X direction). Therefore, the apparatus of the present example can have a configuration in which the mechanism for horizontally moving the fourth robot CR4 and the control unit are omitted.

The CPU in the second embodiment implements a control unit related to the third robot CR3 and the fourth robot CR4 in addition to the functions of the CPU 89a according to the first embodiment, and the storage unit 89b in the second embodiment stores information related to the control of the third robot CR3 and the fourth robot CR4 in addition to the functions according to the first embodiment. Note that, as in the first embodiment, the specific configuration of the CPU is not particularly limited. One CPU may be provided in the entire apparatus, or one or more CPUs may be provided in each block. The same applies to the storage unit 89b.

### Flow of Substrate Processing

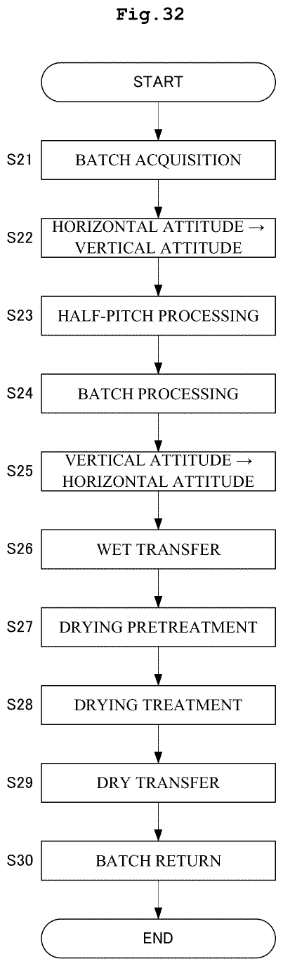

FIG. 32 is a flowchart describing the flow of the substrate processing of the present example. In the substrate processing of the present example, as in the first embodiment, for example, each processing related to surface etching of the substrate W in the manufacturing process of the semiconductor device is performed. Hereinafter, the flow of the substrate processing will be specifically described along the flowchart.
Step S21: As in step S11 of the first embodiment, the carrier C that stores the substrate W to be processed is set in the carrier holding unit 11. The plurality of substrates W is taken out from the carrier C by the collective transfer mechanism 19 and transferred to the forward substrate handover position P1.
Step S22: As in step S12 of the first embodiment, the plurality of substrates W is handed over to the first attitude changing mechanism PCR. The first attitude changing mechanism PCR changes the attitude of the substrate W from the horizontal attitude to the vertical attitude.
Step S23: As in step S13 of the first embodiment, the plurality of substrates W whose attitude have been changed to a vertical attitude is handed over to the pusher mechanism 22. The pusher mechanism 22 changes the arrangement pitch of the substrates W having the full pitch to the half pitch in cooperation with the substrate pickup mechanism WDB.
Step S24: As in step S14 of the first embodiment, the plurality of substrates W transferred to the vertical substrate handover position P2 is transferred to the batch processing region R1 by the substrate transfer mechanism WTR. The plurality of substrates W is subjected to various liquid treatments in a state of forming a lot.
Step S25: As in step S15 of the first embodiment, the plurality of substrates W transferred to the attitude changing unit VHU by the substrate transfer mechanism WTR is handed over to the second attitude changing mechanism 20. The second attitude changing mechanism 20 changes the attitude of the substrates W from the vertical attitude to the horizontal attitude, and causes the plurality of substrates W to wait at the horizontal substrate handover position P3.

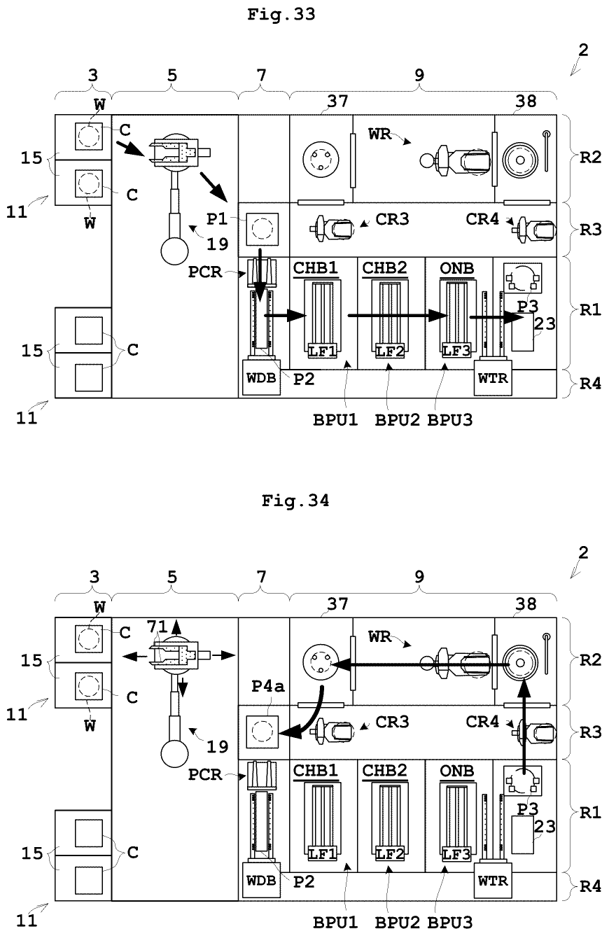

FIG. 33 illustrates substrate transfer in steps S21 to 25. In each process illustrated in FIG. 33, the plurality of substrates W is collectively transferred.
Step S26: The plurality of substrates W waiting at the horizontal substrate handover position P3 is transferred one by one to the substrate drying pretreatment chamber 38 by the fourth robot CR4. That is, the substrate W at the horizontal substrate handover position P3 is held by the CR wet arm 75 of the fourth robot CR4 and carried into an empty substrate drying pretreatment chamber 38 (substrate drying pretreatment chamber 38 that is not being subjected to the drying pretreatment). When the substrate drying pretreatment chamber 38 is in the middle of the drying pretreatment, the fourth robot CR4 waits in a state of not gripping the substrate W until the substrate drying pretreatment chamber 38 becomes empty, acquires one substrate W from the horizontal substrate handover position P3 when the substrate drying pretreatment chamber 38 becomes empty, and transfers the substrate W to the substrate drying pretreatment chamber 38.
Step S27: When the substrate W is carried into the substrate drying pretreatment chamber 38, the shutters of the carry-in port 38a and the carry-out port 38b are closed, and the drying pretreatment is executed inside the chamber. By this treatment, IPA is supplied to the surface of the substrate W.
Step S28: As in step S17 of the first embodiment, the wet transfer mechanism WR transfers the substrate W to be dried into any one of the empty drying chambers 37 (drying chamber 37 that is not being dried) located in the uppermost layer, the middle layer, and the lowermost layer. The drying chamber 37 performs a drying treatment on the carried substrate W.
Step S29: As in step S18 of the first embodiment, the substrate W after the drying treatment is carried out of the chamber by the second robot CR2 or the third robot CR3. Specifically, the substrate W in the drying chamber 37 located at the lowermost layer is transferred to the first return substrate handover position P4a by the dry arm 73c of the third robot CR3. Further, the substrates W in the drying chambers 37 located in the uppermost layer and the middle layer are transferred to the second return substrate handover position P4b by the second robot CR2.

FIG. 34 illustrates substrate transfer in steps S26 to S29. In each process illustrated in FIG. 34, the substrates W in the horizontal attitude are transferred one by one. Note that FIG. 34 illustrates a state in which the substrate W in the drying chamber 37 located at the lowermost layer is transferred to the first return substrate handover position P4a by the third robot CR3.
Step S30: When the predetermined number of substrates W are filled in the path arranged at the first return substrate handover position P4a or the second return substrate handover position P4b by repeating the above-described steps S26 to 29 several times, the substrates W of the path are held by the collective transfer mechanism 19 and returned to the original carrier C. This step is similar to step 19 in the first embodiment.

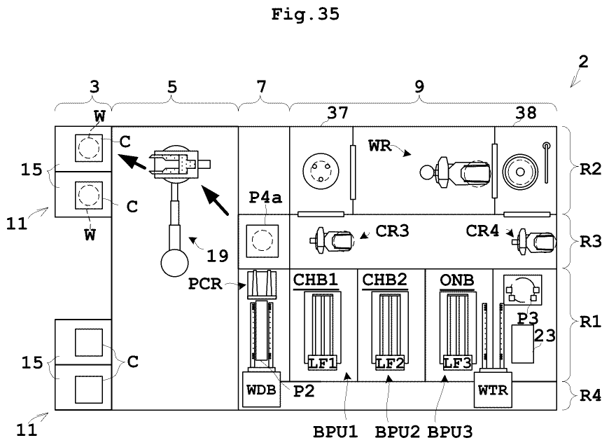

FIG. 35 illustrates a state in which the plurality of substrates W is collectively transferred in step S30. Note that FIG. 35 illustrates a state in which the plurality of substrates W is transferred from the first return substrate handover position P4a. In this manner, the substrate processing by the substrate processing apparatus 2 according to the present example ends.

As described above, according to the present example, the following effects are obtained in addition to effects similar to those of the first embodiment. That is, the fourth robot CR4 of the present example sends the substrate W to the substrate drying pretreatment chamber 38, and the wet transfer mechanism WR receives the substrate W from the substrate drying pretreatment chamber 38. With this configuration, it is not necessary to transfer the substrate W between the wet transfer mechanism WR and the fourth robot CR4, and thus it is possible to provide the substrate processing apparatus 2 capable of more reliably transferring the substrate W and reliably performing the pretreatment of the substrate W to be dried.

The present invention is not limited to the above-described configuration, and modifications can be made as follows.

### Modification 1

The drying chamber 37 described above is a supercritical fluid chamber, but the present invention is not limited to this configuration. The drying chamber 37 may be configured by a chamber capable of spin dry processing.

### Modification 2

The three drying chambers 37 in the single wafer processing region R2 described above are stacked in the vertical direction (Z direction) to form a stack, but the present invention is not limited to this configuration, and the number of drying chambers 37 forming the stack can be appropriately increased or decreased.

### Modification 3

In the above-described single wafer processing region R2, a plurality of stacks in which a predetermined number of the drying chambers 37 are stacked in the vertical direction (Z direction) is provided, but the present invention is not limited to this configuration, and can also be applied to a device having a single stack. In such an apparatus, the right or left stack of the wet transfer mechanism WR in FIG. 19 is omitted.

### Modification 4

The above-described single substrate transfer region R3 is divided into upper and lower sections and has robots independent of the upper section and the lower section, but the present invention is not limited to this configuration. The single substrate transfer region R3 may not be divided by the partition wall, and a single robot that collectively performs transfer executed by each robot may be provided instead of the first robot CR1 and the second robot CR2.

### Modification 5

The above-described first robot CR1 in the single substrate transfer region R3 can access the chamber located in the lowermost layer in the single wafer processing region R2, and the second robot CR2 can access the chambers located in the uppermost layer and the middle layer in the single wafer processing region R2. However, the present invention is not limited to this configuration. The first robot CRI may be able to access the chambers located in the middle layer and the lowermost layer in the single wafer processing region R2, and the second robot CR2 may be able to access the chamber located in the lowermost layer in the single wafer processing region R2 accordingly.

### Reference Signs List

5 supply block
7 transfer block
9 processing block
19 collective transfer mechanism
20 second attitude changing mechanism
20B horizontal holding unit (horizontal substrate support member)
22 pusher mechanism (vertical substrate support member)
37 drying chamber
38 substrate drying pretreatment chamber
72 CR wet arm (handover arm)
73a dry arm (carrying-out arm)
C carrier
CR1 first robot (single substrate transfer mechanism, substrate carrying-out mechanism, and first substrate carrying-out mechanism)
CR2 second robot (second substrate carrying-out mechanism)
P1 Forward substrate handover position
P2 vertical substrate handover position
P3 horizontal substrate handover position
P4 return substrate handover position
P4a first return substrate handover position
P4b second return substrate handover position
PCR first attitude changing mechanism
R1 batch processing region
R2 single wafer processing region
R3 single substrate transfer region
R4 batch substrate transfer region
W substrate
WR wet transfer mechanism (substrate carrying-in mechanism)
WTR substrate transfer mechanism (batch substrate transfer mechanism)

1. A substrate processing apparatus that continuously performs batch processing of collectively processing a plurality of substrates and single wafer processing of processing substrates one by one, the substrate processing apparatus comprising:
a supply block that supplies a plurality of substrates, a transfer block adjacent to the supply block, and a processing block adjacent to the transfer block, wherein
the supply block includes:
a collective transfer mechanism that carries out the plurality of substrates in a horizontal attitude and arranged at predetermined intervals in a vertical direction from a carrier and sends the substrates to a forward substrate handover position in the transfer block, and receives a plurality of substrates in the horizontal attitude and arranged at the predetermined intervals in the vertical direction from a return substrate handover position in the transfer block and stores the substrates in the carrier,
the transfer block includes:
a first attitude changing mechanism that collectively holds the plurality of substrates waiting at the forward substrate handover position and collectively changes an attitude of the plurality of substrates from the horizontal attitude to a vertical attitude, and a vertical substrate support member that causes the plurality of substrates in the vertical attitude to wait at a vertical substrate handover position in the transfer block,
the processing block includes:
a batch processing region having one end side adjacent to the transfer block and another end side extending in a direction away from the transfer block;
a single wafer processing region having one end side adjacent to the transfer block and another end side extending in the direction away from the transfer block;
a single substrate transfer region interposed between the batch processing region and the single wafer processing region and having one end side adjacent to the transfer block and another end side extending in the direction away from the transfer block; and
a batch substrate transfer region provided along the batch processing region and having one end side adjacent to the transfer block and another end side extending in the direction away from the transfer block,
in the batch processing region in the processing block, a plurality of batch processing tanks that collectively perform an immersion treatment on the plurality of substrates in a direction in which the region extends is arranged, and a second attitude changing mechanism that collectively changes an attitude of the plurality of substrates from the vertical attitude to the horizontal attitude at a position farthest from the transfer block and a horizontal substrate support member that causes the plurality of substrates in the horizontal attitude to wait at a horizontal substrate handover position in the batch processing region are further provided,
in the single wafer processing region in the processing block, a substrate carrying-in mechanism in which a plurality of drying chambers for performing a drying treatment of a substrate is arranged in the vertical direction, and a substrate before the drying treatment is carried into the drying chamber, is further provided,
in the single substrate transfer region in the processing block, a single substrate transfer mechanism that receives a substrate in the horizontal attitude from the horizontal substrate handover position and transfers the substrate to the single wafer processing region, and a substrate carrying-out mechanism that carries out a substrate after the drying treatment from the drying chamber to the return substrate handover position in the transfer block are provided, and
the batch substrate transfer region in the processing block includes the vertical substrate handover position defined in the transfer block, and a batch substrate transfer mechanism that collectively transfers the plurality of substrates between each of the batch processing tanks and the second attitude changing mechanism.

2. The substrate processing apparatus according to claim 1, wherein the substrate carrying-in mechanism receives a substrate from the single substrate transfer mechanism.

3. The substrate processing apparatus according to claim 1, wherein
the single wafer processing region includes a substrate drying pretreatment chamber that performs a pretreatment of the drying treatment,
the single substrate transfer mechanism delivers a substrate to the substrate drying pretreatment chamber, and
the substrate carrying-in mechanism receives a substrate from the substrate drying pretreatment chamber.

4. The substrate processing apparatus according to claim 2, wherein
the single substrate transfer mechanism is constituted by a robot that also serves as the substrate carrying-out mechanism,
the single substrate transfer mechanism includes a handover arm that supports the substrate before the drying treatment,
the substrate carrying-out mechanism includes a carrying-out arm that supports the substrate after the drying treatment, and
the carrying-out arm is provided in an upper portion of the handover arm.

5. The substrate processing apparatus according to claim 1, wherein the drying chamber dries the substrate with a supercritical fluid.

6. The substrate processing apparatus according to claim 3, wherein the substrate drying pretreatment chamber predries the substrate with isopropyl alcohol.

7. The substrate processing apparatus according to claim 1, wherein
in the single wafer processing region in the processing block,
stacks of the drying chambers are provided on both sides of the substrate carrying-in mechanism.

8. The substrate processing apparatus according to claim 1, wherein
in the batch substrate transfer region in the processing block,
a first substrate carrying-out mechanism that carries out a substrate in an upper layer of the stacks of the drying chamber, and
a second substrate carrying-out mechanism that carries out a substrate in a lower layer of the stacks of the drying chamber are provided, and
in the transfer block,
a first return substrate handover position at which the first substrate carrying-out mechanism carries out a substrate is set, and
a second return substrate handover position at which the second substrate carrying-out mechanism carries out a substrate is set.
